(19) United States
(12) Patent Application Publication
(10) Pub. No.: US 2024/0403653 A1
(43) Pub. Date: Dec. 5, 2024

(54) Method and Apparatus

(71) Applicant: Oxa Autonomy Ltd, Oxford (GB)

(72) Inventors: Sampo Kuutti, Oxford (GB); Horia Porav, Oxford (GB); Ben Upcroft, Oxford (GB); Paul Newman, Oxford (GB)

(73) Assignee: Oxa Autonomy Ltd, Oxford (GB)

(21) Appl. No.: 18/701,594

(22) PCT Filed: Oct. 17, 2022
(86) PCT No.: PCT/GB2022/052636

§ 371 Date: Apr. 15, 2024

(30) Foreign Application Priority Data
Oct. 15, 2021 (GB) 2114809.3

(51) Int. Cl. G06N 3/092; B60W 60/00; G06N 3/0464

(52) U.S. Cl. CPC G06N 3/092; G06N 3/0464; B60W 60/001

(57) ABSTRACT

A computer-implemented method of generating trajectories of actors, the method comprising: simulating a first scenario comprising an environment having therein an ego-vehicle, a set of actors, including a first actor, and optionally a set of objects, including a first object, wherein simulating the first scenario comprises using a first trajectory of the first actor; observing, by a first adversarial reinforcement learning agent, a first observation of the environment, for example the ego-vehicle, a second actor of the set thereof and/or the first object of the set thereof, in response to the first trajectory of the first actor; and generating, by the first agent, a second trajectory of the first actor based on the observed first observation of the environment.

### FIELD

The present invention relates to autonomous vehicles.

### BACKGROUND TO THE INVENTION

Conventional testing of control software (also known as AV stack) of autonomous vehicles (AVs), for example according to SAE Level 1 to Level 5, is problematic. For example, a conventional testing approach typically involves a manual (i.e. human) and effort-intensive procedure:
1. Test drive the AV in real-world roads OR in simulated environments with randomly generated traffic. Collect data on the scenarios encountered and the AV behaviour.
2. Identify challenging scenarios based on AV behaviour (e.g. scenarios where the safety driver had to intervene, AV did not brake sufficiently early etc).
3. Re-create challenging scenarios in simulation, add random noise to scenario parameters (e.g. position & velocities of nearby vehicles/pedestrians/cyclists).

This approach is not only massively expensive and time-consuming, but requires capturing low-probability events, which is many times impossible. While randomising the scenario parameters based on the initial scenario identified through real-world driving allows for expanding the number of scenarios, this is very inefficient due to the number of miles required to identify these rare edge-case scenarios. Failing to discover defects in the control software increases risk to the AV and to occupants thereof.

Hence, there is a need to AVs, for example testing thereof.

### SUMMARY OF THE INVENTION

A first aspect provides a computer-implemented method of generating trajectories of actors, the method comprising:
simulating a first scenario comprising an environment having therein an ego-vehicle, a set of actors, including a first actor, and optionally a set of objects, including a first object, wherein simulating the first scenario comprises using a first trajectory of the first actor;
observing, by a first adversarial reinforcement learning agent, a first observation of the environment, for example the ego-vehicle, a second actor of the set thereof and/or the first object of the set thereof, in response to the first trajectory of the first actor; and
generating, by the first agent, a second trajectory of the first actor based on the observed first observation of the environment.

A second aspect provides a computer-implemented method of simulating scenarios, the method comprising:
generating a first trajectory of a first actor of a set of actors according to the first aspect;
simulating a first scenario comprising an environment having therein an ego-vehicle, the set of actors, including the first actor, and optionally a set of objects, including a first object, wherein simulating the first scenario comprises using the generated first trajectory of the first actor; and
identifying a defect of the ego-vehicle in the first scenario.

A third aspect provides a computer-implemented method of developing an ego-vehicle, the method comprising:
simulating a scenario according to the second aspect; and
remedying the identified defect of the ego-vehicle.

A fourth aspect provides a computer comprising a processor and a memory configured to perform a method according to the first aspect, the second aspect and/or the third aspect.

A fifth aspect provides a computer program comprising instructions which, when executed by a computer comprising a processor and a memory, cause the computer to perform a method according to the first aspect, the second aspect and/or the third aspect.

A sixth aspect provides a non-transient computer-readable storage medium comprising instructions which, when executed by a computer comprising a processor and a memory, cause the computer to perform a method according to the first aspect, the second aspect and/or the third aspect.

According to an aspect of the present disclosure, there is provided a computer-implemented method of generating a new adversarial scenario involving an autonomous vehicle and an agent, the computer-implemented method comprising: performing reinforcement learning to train the agent using an autonomous vehicle software stack in a reinforcement learning environment to generate one or more episodes, the one or more episodes each representing an adversarial scenario terminating in a failure of the autonomous vehicle software stack; generating a plurality of descriptors based on the or each episode; and storing the plurality of descriptors in a database.

The autonomous vehicle may be an ego-vehicle. An adversarial scenario may be one involving a failure of the autonomous vehicle software stack. The agent may be a machine learning model. The machine learning model may comprise a neural network.

In an embodiment, the computer-implemented method may comprise clustering the plurality of descriptors for the or each episode, and wherein the storing the plurality of descriptors comprises storing the cluster of descriptors in the database.

The computer-implemented method further comprising generating a new descriptor by moving away from the cluster of descriptors in a descriptor space.

The moving away from the cluster of descriptors in the descriptor space may comprise: identifying a barycentre for the cluster; moving away from the barycentre in a unit direction by a unit amount to a new descriptor location; and generating the new descriptor as a descriptor at the new descriptor location.

The moving away from the cluster of descriptors in the descriptor space may comprise: identifying a set boundary for the cluster; moving away from the boundary in a unit direction by a unit amount to a new descriptor location; and generating the new descriptor as a descriptor at the new descriptor location.

The moving away from the cluster of descriptors in the descriptor space may comprise: identifying a set boundary for the cluster; moving away from the boundary in a locally normal direction by a unit amount to a new descriptor location; and generating the new descriptor as a descriptor at the new descriptor location.

The set boundary may be identified using a signed distance function.

The one or more episodes may comprise a plurality of episodes and the clustering the plurality of episodes may comprise generating a plurality of clusters and the storing the clusters comprises storing the plurality of clusters in the database, wherein the moving away from the cluster may comprise moving away from the plurality of clusters by: determining a union set between each cluster; determining a difference between the cluster space and the union set; determining a barycentre for the difference; and generating the new descriptor as a descriptor at the barycentre of the difference.

The computer-implemented method may further comprise: generating a seed state from the new descriptor; and re-performing: the reinforcement learning using the seed state, the generating the plurality of descriptors, and the storing the plurality of descriptors.

The computer-implemented method may further comprise: re-initialising the agent; and re-performing: the reinforcement learning using the re-initialised agent, the generating the plurality of descriptors, and the storing the plurality of descriptors.

The environment may further comprises contextual data.

The contextual data may comprise one or more internal maps and/or one or more external maps.

The computer-implemented method may further comprise: changing the contextual data in the environment; and re-performing: the reinforcement learning using the changed contextual data, the generating the plurality of descriptors, and the storing the plurality of descriptors.

The episode may comprise a plurality of points, wherein each point may comprise a state output by the environment and an action output by the agent. The points may be temporal points or positional points of the autonomous vehicle.

The generating the plurality of descriptors may comprise encoding the plurality of respective points to a latent space.

The failure may comprise an event selected from a list including: a collision between the agent and the autonomous vehicle software stack, a distance between the agent and the autonomous vehicle software stack being less than a minimum distance threshold, a deceleration of the autonomous vehicle software stack being greater than a deceleration threshold, an acceleration of the autonomous vehicle software stack being greater than an acceleration threshold, and a jerk of the autonomous vehicle software stack being greater than a jerk threshold.

According to an aspect of the present disclosure, there is provided a computer implemented method of generating an agent from a scenario involving an autonomous vehicle, the computer-implemented method comprising: performing reinforcement learning to train the agent using an autonomous vehicle software stack in a reinforcement learning environment to generate one or more episodes terminating in a failure of the autonomous vehicle software stack, the one or episodes each representing an adversarial scenario; reperforming the reinforcement learning of the agent to generate a new episode; comparing the new episode to the one or more episodes; and generating the agent by cloning the agent trained using the reinforcement learning based on the comparison.

The failure may comprise an event selected from a list including: a collision between the agent and the autonomous vehicle software stack, a distance between the agent and the autonomous vehicle software stack being less than a minimum distance threshold, a deceleration of the autonomous vehicle software stack being greater than a deceleration threshold, an acceleration of the autonomous vehicle software stack being greater than an acceleration threshold, and a jerk of the autonomous vehicle software stack being greater than a jerk threshold.

The environment may further comprise contextual data.

The contextual data may comprise one or more internal maps and/or one or more external maps.

The episode may comprise a plurality of points, wherein each point comprises a state output by the environment and an action output by the agent. The points may be temporal points or positional points of the autonomous vehicle.

The comparing the new episode to the one or more episodes may comprise determining a variance between the new episode and the one or more episodes, and wherein the generating the agent by cloning the agent trained using the reinforcement learning based on the comparison may comprise cloning the agent trained using the reinforcement learning when the variance is below a variance threshold.

According to an aspect of the present disclosure, there is provided a computer-implemented method of generating a new adversarial scenario involving an autonomous vehicle and an agent, the method comprising: performing reinforcement learning to train the agent using a proxy of an autonomous vehicle software stack in a reinforcement learning environment to generate one or more episodes, the one or more episodes each representing an adversarial scenario terminating in failure of the proxy of the autonomous vehicle software stack; generating a plurality of descriptors based on the or each episode; and storing the plurality of descriptors in a database.

The computer-implemented method may further comprise clustering the plurality of descriptors for the or each episode, and wherein the storing the plurality of descriptors may comprise storing the cluster of descriptors in the database.

The computer-implemented method may further comprise generating a new descriptor by moving away from the cluster of descriptors in a descriptor space.

The moving away from the cluster of descriptors in the descriptor space may comprise: identifying a barycentre for the cluster; moving away from the barycentre in a unit direction by a unit amount to a new descriptor location; and generating the new descriptor as a descriptor at the new descriptor location.

The moving away from the cluster of descriptors in the descriptor space may comprise: identifying a set boundary for the cluster; moving away from the boundary in a unit direction by a unit amount to a new descriptor location; and generating the new descriptor as a descriptor at the new descriptor location.

The moving away from the cluster of descriptors in the descriptor space may comprise: identifying a set boundary for the cluster; moving away from the boundary in a locally normal direction by a unit amount to a new descriptor location; and generating the new descriptor as a descriptor at the new descriptor location.

The set boundary may be identified using a signed distance function.

The one or more episodes may comprises a plurality of episodes and the clustering the plurality of episodes comprises generating a plurality of clusters and the storing the clusters comprises storing the plurality of clusters in the database, wherein the moving away from the cluster may comprise moving away from the plurality of clusters by: determining a union set between each cluster; determining a difference between the cluster space and the union set; determining a barycentre for the difference; and generating the new descriptor as a descriptor at the barycentre of the difference.

The computer-implemented method may further comprise: generating a seed state from the new descriptor; and re-performing: the reinforcement learning using the seed state, the generating the plurality of descriptors, and the storing the plurality of descriptors.

The computer-implemented method may further comprise: re-initialising the agent; and re-performing: the reinforcement learning using the re-initialised agent, the generating the plurality of descriptors, and the storing the plurality of descriptors.

The environment may further comprise contextual data.

The contextual data may comprise one or more internal maps and/or one or more external maps.

The computer-implemented method may further comprise: changing the contextual data in the environment; and re-performing: the reinforcement learning using the changed contextual data, the generating the plurality of descriptors, and the storing the plurality of descriptors.

The episode may comprise a plurality of points, wherein each point may comprises a state output by the environment and an action output by the agent. The plurality of points may be temporal points or positional points of the autonomous vehicle.

The generating the plurality of descriptors may comprise encoding the plurality of respective points to a latent space.

The failure may comprise an event selected from a list including: a collision between the agent and the autonomous vehicle software stack, a distance between the agent and the autonomous vehicle software stack being less than a minimum distance threshold, a deceleration of the autonomous vehicle software stack being greater than a deceleration threshold, an acceleration of the autonomous vehicle software stack being greater than an acceleration threshold, and a jerk of the autonomous vehicle software stack being greater than a jerk threshold.

The proxy may comprise a machine learning model, and the machine learning model is optionally a neural network, and the neural network is optionally a convolutional neural network.

According to another aspect, there is provided a computer-implemented method of generating an agent from a scenario involving an autonomous vehicle, the computer-implemented method comprising: providing an agent trained using reinforcement learning in an environment with a proxy of an autonomous vehicle software stack; performing reinforcement learning to optimise the agent using a full autonomous vehicle software stack upon which proxy is based.

This aspect may be alternatively expressed as a computer-implemented method of a new adversarial scenario involving an autonomous vehicle and an agent, the method comprising: providing an agent trained using reinforcement learning in an environment with a proxy of an autonomous vehicle software stack; performing reinforcement learning to optimise the agent using a full autonomous vehicle software stack upon which proxy is based; generating one or more episodes when optimising the agent; and generating a plurality of descriptors for the other each episode.

The agent may comprise providing the agent trained when performing the foregoing aspect computer-implemented method.

According to an aspect of the present disclosure, there is provided a computer-implemented method of generating anomalous trajectory data for an agent in a scenario of an autonomous vehicle, the computer-implemented method comprising: receiving, by an adversarial machine learning model, contextual data, the contextual data including non-anomalous trajectory data of the agent; generating, by the adversarial machine learning model, anomalous trajectory data from the contextual data; and storing the anomalous trajectory data in a database.

The autonomous vehicle may be an ego-vehicle.

The adversarial machine learning model may comprise a generative adversarial network trained to generate anomalous trajectory data from non-anomalous trajectory data.

The computer-implemented method may further comprise; receiving, by the adversarial machine learning model, noise, wherein the generating, by the adversarial machine learning model, anomalous trajectory data from the contextual data comprises generating the anomalous trajectory data based on the noise.

The contextual data may further comprise internal maps and/or external maps.

The non-anomalous trajectory data may comprises trajectory data that is associated with a non-infraction between the agent and the autonomous vehicle.

The anomalous trajectory data may comprise trajectory data associated with an infraction between the agent and the autonomous vehicle, or trajectory data that is not associated with a non-infraction between the agent and the ego-vehicle.

The infraction may comprise an event selected from a list including a collision, coming to within a minimum distance, deceleration of the autonomous vehicle above a deceleration threshold, acceleration of the autonomous vehicle above an acceleration threshold, and jerk of the autonomous vehicle above a jerk threshold. Expressed differently, the event may be an event selected from a list including: a collision between the agent and the autonomous vehicle software stack, a distance between the agent and the autonomous vehicle software stack being less than a minimum distance threshold, a deceleration of the autonomous vehicle software stack being greater than a deceleration threshold, an acceleration of the autonomous vehicle software stack being greater than an acceleration threshold, and a jerk of the autonomous vehicle software stack being greater than a jerk threshold According to an aspect of the present disclosure, there is provided a computer-implemented method of training an adversarial machine learning model to generate anomalous trajectory data, the computer-implemented method comprising: providing, as inputs to the adversarial machine learning mode, contextual data, the contextual data including non-anomalous trajectory data of the agent; generating, by the adversarial machine learning model, predicted anomalous trajectory data from the contextual data; calculating a loss between the predicted anomalous trajectory data and the non-anomalous trajectory data; and changing a parameterisation of the adversarial machine learning model to reduce the loss.

The adversarial machine learning model may comprise a generative adversarial network.

The generative adversarial network may be a first generative adversarial network forming part of a cycle-generative adversarial network comprising a second generative adversarial network, wherein the method may comprise: providing, as inputs to the second generative adversarial network, the generated anomalous trajectory data; generating, by the second generative adversarial network, reconstructed non-anomalous trajectory data; calculating a loss between the reconstructed non-anomalous trajectory data and the non-anomalous trajectory data; and changing a parameterisation of the second generative adversarial network to reduce a second loss, wherein the loss is a first loss.

The second loss may comprise a reconstruction loss and/or an adversarial loss.

The loss may comprise an adversarial loss and/or a prediction loss.

The non-anomalous trajectory data may be labelled.

The contextual data further may comprise internal maps and/or external maps.

The non-anomalous trajectory data may comprise trajectory data that is associated with a non-infraction between the agent and the autonomous vehicle.

The anomalous trajectory data may comprise trajectory data associated with an infraction between the agent and the autonomous vehicle, or trajectory data that is not associated with a non-infraction between the agent and the ego-vehicle.

The infraction may comprise an event selected from a list including: a collision between the agent and the autonomous vehicle, a distance between the agent and the autonomous vehicle being less than a minimum distance threshold, a deceleration of the autonomous vehicle being greater than a deceleration threshold, an acceleration of the autonomous vehicle being greater than an acceleration threshold, and a jerk of the autonomous vehicle being greater than a jerk threshold.

A transitory, or non-transitory, computer-readable medium, including instructions stored thereon that, when executed by one or more processors, cause the one or more processors to performing the method of any preceding claim.

### DETAILED DESCRIPTION OF THE INVENTION

According to the present invention there is provided a method, as set forth in the appended claims. Also provided is a computer program, a computer and a non-transient computer-readable storage medium. Other features of the invention will be apparent from the dependent claims, and the description that follows.

### Method

The first aspect provides a computer-implemented method of generating trajectories of actors, the method comprising:
simulating a first scenario comprising an environment having therein an ego-vehicle, a set of actors, including a first actor, and optionally a set of objects, including a first object, wherein simulating the first scenario comprises using a first trajectory of the first actor;
observing, by a first adversarial reinforcement learning agent, a first observation of the environment, for example the ego-vehicle, a second actor of the set thereof and/or the first object of the set thereof, in response to the first trajectory of the first actor; and
generating, by the first agent, a second trajectory of the first actor based on the observed first observation of the environment.

In this way, the second trajectory of the first actor, for example to be used in another scenario, is an informed, rather than a random or systematic, perturbation or change, for example a maximally informed adversarial perturbation, of the first trajectory, since the second trajectory is generated by the first agent based on observing the environment, for example based on observing the ego-vehicle, the set of actors, including or excluding the first actor, and optionally the set of objects, including the first object. In this way, the method more efficiently generates trajectories that explore the environment more effectively since the generating is informed, thereby improving discovery of defects of the ego-vehicle and hence of the control software of the corresponding vehicle. For example, the trajectories may be generated via learning, via heuristics and extracted from driving statistics and/or a compliment thereof. For example, as described below in more detail, the trajectories may be generated via rejection sampling, thereby sampling trajectories outside of normal or expected scenarios (i.e. the complement of normal space or (1−N). In this way, scenarios may be recreated having informatively generated, for example modified, trajectories. By improving discovery of defects of the ego-vehicle and hence of the control software of the corresponding vehicle, safety of the control software is improved, thereby in turn improving safety of the corresponding vehicle and/or occupants thereof. In contrast, conventional methods of generating trajectories explore the environment randomly or systematically, thereby potentially failing to discover defects while extending runtime and/or requiring increased computer resources.

In one example, generating, by the first agent, the second trajectory of the first actor based on the observed first observation of the environment comprises exploring, by the first agent, outside a normal space (i.e. normal or expect scenarios), for example as described below with respect to points E, I and F.

In other words, instead of identifying initial scenarios through road testing, the method is used to generate low-probability events, thereby massively reducing the amount of miles needed to drive for verification and validation, for example. Similarly, instead of randomly perturbing the trajectories of actors in the scenario, the method generates these trajectories from a learned adversarial model, which through simulation can interact with the environment and react to the AV's actions, for example. In this way, the amount of difficult and low-probability scenarios generated per miles driven in simulation and per unit of time is increased.

Hence, the learned adversarial agent generates trajectories of dynamic actors (e.g. vehicles/pedestrians/cyclists), which the AV would find challenging. The adversarial agent learns by interacting with the (simulated) driving environment and the target AV system. Therefore, over time, the adversarial agent learns any potential weaknesses of the AV, and efficiently generates low-probability driving scenarios in which the AV is highly likely to behave sub-optimally. These scenarios are then used as proof of issues in the target AV system for verification and validation purposes and may be used as training data to further improve the capabilities of the AV system. Similarly, the method may be used for regression and/or progression testing. Similarly, the method can be used to parameterise deterministic tests.

The method is a computer-implemented method. That is, the method is implemented by a computer comprising a processor and a memory. Suitable computers are known.

The method comprises simulating the first scenario. Computer-implemented methods of simulating (i.e. in silico) scenarios are known. Generally, a scenario is a description of a driving situation that includes the pertinent actors, environment, objectives and sequences of events.

For example, the scenario may be composed of short sequences (a few to tens of seconds) with four main elements, such as expressed in a 2D bird's eye view:
1. Scene or environment (e.g. road, lanes, obstacles);
2. Ego-vehicle and its trajectory;
3. Actors (pedestrians, other vehicles etc) and their respective trajectories; and
4. Optionally, objects in the scene (traffic lights, static bikes and cars).

Additional context elements (actors, objects) may be added to better express the scene and scenario composition.

The scenario comprises the environment having therein the ego-vehicle, the set of actors, including the first actor (i.e. at least one actor), and optionally the set of objects, including the first object. The environment, also known as a scene, typically includes one or more roads having one or more lanes and optionally, one or more obstacles, as understood by the skilled person. Generally, an ego-vehicle is a subject connected and/or automated vehicle, the behaviour of which is of primary interest in testing, trialing or operational scenarios. It should be understood that the behaviour of the ego-vehicle as defined by the control software (also known as AV stack) thereof. In one example, the first actor is a road user, for example a vehicle, a pedestrian or a cyclist. Other road users are known. In one example, the first object comprises and/or is infrastructure, for example traffic lights, or a static road user. In one example, the set of actors includes A actors wherein A is a natural number greater than or equal to 1, for example 1, 2, 3, 4, 5, 6, 7, 8, 9, 10 or more. In one example, the set of objects includes 0 objects wherein O is a natural number greater than or equal to 1, for example 1, 2, 3, 4, 5, 6, 7, 8, 9, 10 or more.

Simulating the first scenario comprises using the first trajectory of the first actor. It should be understood that actors have associated trajectories. The first trajectory may be described using a descriptor, as described below.

The method comprises observing, by the first adversarial reinforcement learning agent (also known herein as agent or adversarial agent), the first observation of the environment, for example the ego-vehicle, a second actor of the set thereof and/or the first object of the set thereof, in response to the first trajectory of the first actor. That is, the first trajectory of the first actor may cause a change to the environment. For example, the trajectory of the ego-vehicle and/or the trajectory of the second actor may change in response to the first trajectory of the first actor, for example to avoid a collision therewith. In one example, the first observation of the environment is of the ego-vehicle. In one example, observing, by the agent, the first observation of the environment comprises observing, by the agent, a first behaviour of the environment, wherein the first behaviour comprises the first observation. In one example, the method comprises providing one or more reinforcement learning agent, for example adversarial and/or non-adversarial RL agents, cooperating and/or interacting with the first agent, the set of actors and/or the set of objects.

The method comprises generating, by the first agent, the second trajectory of the first actor based on the observed first observation of the environment. That is, the first agent learns from the first trajectory of the first actor and the observed first observation in response thereto and generates the second trajectory using this learning. In other words, generating the second trajectory is informed by the first observation, as described previously.

Particularly, the inventors have identified that conventional methods:
i. Do not consider the similarity of the generated scenarios, as the system can continue to exploit previously found weaknesses (or something very similar to already known weaknesses) in the AV behaviour without discovering new issues. Discovering diverse adversarial scenarios is key to efficient automated issue discovery.
ii. Do not consider or gauge how informative the scenarios seeds are for each training episode. Do not consider or gauge how informative the generated scenarios are during the training process. Similarly, existing systems do not have in place measures for limiting catastrophic forgetting while avoiding mode collapse.
iii. Start conditions for the adversarial scenarios are typically generated by either randomly choosing actor locations or choosing them by copying previously discovered difficult scenarios. A wider variety of scenarios could be discovered by predicting what start conditions would likely be difficult or novel to the AV stack, and using this to generate start conditions for the scenarios in an informed and automated manner.
iv. Generally do not attempt to output test parametrisations (e.g. regression, progression) or defect reports as one of the direct results
v. Use a single adversarial agent (do not consider multiple adversaries cooperating to create more complex adversarial scenarios).
vi. Consider AV as a black box and use high-level metrics such as collisions, instead of being able to exploit individual sub-systems in the AV stack based on their individual performance metrics.
vii. Focus on generating collisions by any means necessary, without considering if collisions are preventable. If the collision is not preventable (e.g. an object appears at a distance less than the AV's minimum braking distance in front of it or a pedestrian runs into a stationary AV) the collision is not caused by an AV and therefore does not necessarily represent an issue in the technology used.

Hence, as described herein, the inventors have improved conventional methods by, for example:
a. Similarity and diversity of the generated scenarios (to maximise coverage)—scenario and trajectory descriptors, scenario and trajectory matchers, anomaly detection via reconstruction scenario or trajectory loss, DB of scenario and trajectory descriptors,
b. Informed Diversification of seed and start conditions (exploration) for the adversarial scenarios
c. Predictive reward/mixture of policies to prevent catastrophic forgetting—Mixture of Policies or Per-category policy
d. Learn to convert normal scenarios to anomalous scenarios
e. Dynamic Time Warping Matching for Scenarios and Learned matching for Scenarios
f. Two stage operation: coarse-to-fine, where a learned, possibly differentiable black-box replica of the AV stack or one or more of its (sub)components is first used to efficiently reduce the search space, followed by adversarial fine tuning with the real AV stack in the Simulator
g. Deriving actionable items from issue discovery—“field” bugs or defect/bug report
h. Deriving actionable items from issue discovery—parameterizing regression and progression tests
i. Easier reproduction and exploitation of real-world scenarios—learned encoders and general purpose scenario and trajectory descriptors allow us to transform an existing real world scenario into a latent encoding and then sample around it in an informed way, as opposed to manual recreation of scenarios

### A. Trajectory and Context Encoding (Descriptors)

In one example, the method comprises defining the generated second trajectory as a series of descriptors for respective locations, for example as description-location pairs, in which the description includes one or more components relating to the actor or agent, the ego-vehicle, other actors and the environment. For example, the descriptors may be represented as a series T*(X+N) for T time steps, with X-D positional encoding and N-D encoding for other traffic participants, road configuration and scene context, as described with respect to FIG. 1. Optionally, the descriptors may be represented with normalisation, agent-centric or world-centric expression of coordinates and contexts.

In one example, the series of descriptors are heuristics-based and/or learned. That is, the descriptors may be heuristics-based (e.g. different fields dedicated to specific pieces of information) or learned (e.g. a latent encoding of a scene/scenario).

In one example, the method comprises deriving the series of descriptors from data comprising physical data and/or simulation data of scenarios. That is, the descriptors may be derived from both real-world (i.e. physical) data (see below for more details on automatically labelling sequential data) and from simulation data. This means that they can be used as both INPUTS to and OUTPUTS from systems if needed. This allows for a large degree of component interchangeability and for easy storage, comparison and interoperability of real-world data, simulation data and outputs from the processes described below.

### B. Labelling Data

In one example, the method comprises labelling the data, for example by applying a perception model thereto, and wherein deriving the series of descriptors from the data comprises deriving the series of descriptors from the labelled data. That is, the data for generating the descriptors is collected and automatically labelled, for example by applying (learned and heuristics-based) perception models to existing sequential data. Perception models may include image level semantic segmentation and object detection, optical flow etc, laser/LIDAR semantic segmentation and object detection etc, RADAR object detection/velocity estimation, large scale scene understanding etc. Post-processing, smoothing etc can be performed using inertial data and vehicle sensor data etc. Any process with high recall and decent precision may be applied to enrich the data.

Generally, labelling the data using a plurality of techniques, for example by combining perception models and heuristics-based methods optionally together with high quality HD maps, is preferable since artefacts, more generally intermediary features, resulting from the individual techniques may be used independently. In contrast, an end-to-end technique cannot make use of intermediary features.

Contrary to usual expectations, some noise stemming from reduced performance of applied perception models may be beneficial when labelling data for adversarial scenarios, allowing for the distribution of perception defects to be reflected in the generated scenarios. That is, having noisy labels may be an advantage, directly modelling perception in real world. For example, a pedestrian drop out in one or more frames is beneficial for training and/or defect discovery.

For example, the output of localisation may be combined with a map. For example, a perception model may be used for labelling of road edges or lane markings on one passage or trajectory of a road or lane thereof and the labelling may be automatically applied to labelling of other passages or trajectories of the road or the lane thereof or of another road or lane thereof. It should be understood that the agent requires sufficiently accurate and/or precise positions of the ego-vehicle and actors and layouts of the roads.

In one example, the method comprises identifying respective locations of vehicles from the physical data and/or respective locations of ego-vehicles from the simulation data and wherein deriving the series of descriptors from the data comprises deriving the series of descriptors using the identified respective locations of the vehicles and/or the identified respective locations of the ego-vehicles. That is, localisation techniques can be applied to understand the location of the ego-vehicle in a scene.

### C. Avoiding Mode Collapse; Ensuring Novelty

In one example, generating, by the first agent, the second trajectory of the first actor comprises predictively or reactively generating, by the first agent, the second trajectory of the first actor. That is, the second trajectory may be generated predictively (known before taking an action) or reactively (known after taking an action). Generally, reactive methods are less efficient—e.g. classifying a mode collapse after it has happened and discarding the scenario or even the entire agent. However, reactive is easier—identify usefulness post-hoc and act on it. In contrast, predictive is harder but more efficient—it helps to minimize wasted resources and time, speeding up issue discovery

In one example, the method comprises determining a mutual similarity of a candidate trajectory for the first actor generated by the first agent and a reference trajectory and optionally, generating, by the first agent, the second trajectory of the first actor by modifying the candidate trajectory based on the determined mutual similarity or excluding the candidate trajectory based on the determined mutual similarity.

It should be understood that the candidate trajectory is a candidate for the second trajectory and the reference trajectory may be the first trajectory or a stored trajectory, for example stored in a database and accessed selectively. For example, the candidate trajectory may be compared with trajectories included in a database thereof, which are accessed exhaustively or as a subset based on a classification relevant to the scenario.

One simple approach involves databases of descriptors of trajectories and contexts (along with potential uses of databases for EU, NA, etc. that identify many accidents and the causes). A matching process (learned AND/OR heuristics-based) can be used to determine the similarity of descriptors (hence the similarity of scenarios) and take decision (discard scenario, adjust scenario etc).

In one example, the method comprises rewarding the first agent according to a mutual dissimilarity of the first trajectory and the second trajectory. In this way, the first agent is rewarded for generating novel trajectories.

### D. Matching

In one example, the method comprises matching the generated second trajectory and a reference trajectory.

Two or more sets of descriptors that each encode a particular scenario or trajectory of a dynamic agent can be matched at multiple scales, levels and granularities. This allows for the following:
Matching of trajectories and scenarios that have a similar shape but have been captured on different timescales or with different resolutions/number of time step; and/or
Matching of trajectories and scenarios that have a different shape but come from environments or scenes with different configurations (road structures, positions of actors and ego-vehicle, position in lanes, transitions from areas dedicated to pedestrians to areas dedicated to vehicles <pavement-to-road> etc.); and/or
Matching or filtering of trajectories and scenarios initially based on a subportion of the descriptor length, then on a different subportion and so on, yielding a hierarchical or tree-like family of relationships between different trajectories and scenarios.

One example of matching involves an initial positional matching or filtering using Dynamic Time Warping, followed by one or more stages of matching of other portion of the descriptors based on heuristics (such as Euclidean distance), learned methods (e.g. contrastive or margin) and/or custom combinations of learned and hard-coded rules.

In one example, matching the generated second trajectory and the reference trajectory comprises matching one or more portions of the generated second trajectory and the reference trajectory.

### E. Reconstruction

In one example, the method comprises encoding the generated second trajectory and optionally decoding the encoded second trajectory, computing a reconstruction quality of the decoded second trajectory and labelling the generated second trajectory according to the computed reconstruction quality.

In one example, the method comprises decoding an encoded trajectory, encoding the decoded trajectory and computing a reconstruction quality of the encoded trajectory.

That is, the descriptors may also be obtained or encoded via learned methods, which allows for automatic extraction and description of large scale sequential data. This is helpful for a number of reasons:
In certain cases it allows for expanding the richness of expressivity of the descriptors as compared to hand-crafted descriptor fields;
It allows for automatic (self-supervised in many cases) processing of sequential data;
It allows real-worlds scenarios of interest to be automatically encoded (and subsequently sampled from in an informed way);
If used in a variational context, it allows for sampling using arbitrary probability distributions;
Converged learned models may be used to perform anomaly detection by measuring the reconstruction error of an input. A poor reconstruction would indicate an anomaly—the scenario being tested is outside of the distribution of training scenarios. An anomaly can be interpreted, amongst others, as a novel scenario or an adversarial scenario.

That is, this allows determination of whether the input (i.e. the generated trajectory) is from within a normal distribution or outside a normal distribution i.e. has the agent been trained using the input.

Hence, generated trajectories that are within the normal distribution of behaviours (e.g. of the first actor) will have been seen and will be correctly encoded/decoded while generated trajectories from outside the normal distribution of behaviours will not be correctly encoded.

There are two options of using this system:
1. Encode the trajectory to a latent space presentation, decode the latent space presentation to a reconstructed trajectory and measure the reconstruction error;
2. Decode a latent space presentation to a decoded trajectory, encode the decoded trajectory to a reconstructed latent space presentation and measure the reconstruction error;
The second option is self-supervised and hence is preferred—the input and the output are the sole components—no labelling is required.

### F. Seeding

In one example, the method comprises seeding an initial state of the first scenario and initializing the first scenario with the seeded initial state.

Generally, RL agents are good at exploitation and hence do eventually discover defects in the AV stack, for example. However, RL agents are generally not good at exploration, which increases an efficiency of testing, for example.

The inventors have identified that the first RL agent may be induced to explore by providing maximally informed start conditions, for example by training as described herein and rewarding for exploring novel states.

In more detail, generating trajectories and scenarios is computationally cheap, but testing them in the SIM is computationally expensive. Several procedures can be used to reduce the search space:
Some methods can be used to discard a scenario after being tested, in a reactive fashion (using some or all of the methods in points C., D. and E. above)
Some methods can be used to adjust or discard a scenario as it is being tested in a predictive fashion (using some or all of the methods in points C., D. and E. above)
Some methods can be used to informatively reduce the number of starting or seed conditions (see below).

A proposed method for reducing the number of seed conditions is depicted in FIG. 6. A learned conditional trajectory model is trained to either predict trajectories or generate plausible trajectories (hallucinate) using a combination of real-world data and/or simulation data and/or previously generated adversarial trajectories.

At test time, conditional on a new scene layout (e.g. a previously unencountered road configuration or traffic situation or a portion of a map), the learned model can be used to sample both plausible starting conditions, and plausible future trajectory points given a set of previous trajectory points.

This allows for large-scale informed sampling of scene configurations, scenario seeds and starting points. Additionally, this enables informed Exploration during Reinforcement Learning to balance out Exploitation both to improve coverage and to minimize the chances of Catastrophic forgetting and mode collapse.

In one example, seeding the initial state of the first scenario comprises selecting the initial state from a plurality of initial states. That is, the initial state is purposefully, rather than randomly or systematically, selected, for example so as to optimise exploration.

### G. Rewards

In one example, the method comprises rewarding the first agent according to a novelty, for example a short-term novelty and/or a long-term novelty, of the generated second trajectory. In this way, exploration is rewarded.

In more details, the first agent may be rewarded for the novelty of states visited—one example is a voxelized grid to encode extra novelty rewards:
Intrinsic rewards incentivise the RL agent to seek new states and therefore lead to more diverse trajectories taken during training
Rewards can be short-term (e.g. episodic) or long-term (across the training run of the agent), or a combination of both where short-term and long-term novelty is balanced against each other with a scaling coefficient
An example measure of long-term novelty can be obtained by Random Network Distillation (RND). RND uses two networks; a randomly initialised un-trained convolutional neural network (random network) and a predictor convolutional neural network (predictor network) trained during RL training. The predictor network aims to predict the output of the random network for states seen by the RL network. Novel states result in high error in the predictor network's predictions. (This is somewhat similar to using encoders and reconstruction losses, but the RND is trained only on the RL model's observations—rather than a static dataset—so the predictor network's inference errors are specific to a given RL training run. It does however add computation overhead to RL training as it adds an extra network to train).

In one example, the method comprises measuring the novelty, for example using a random network distillation, RND.

### H. Mode Collapse

In one example, the method comprises assessing mode collapse of the first agent and adapting the first agent based on a result of the assessment.

Mode Collapse is a major issue with Deep Learning, and even more so with Deep Reinforcement Learning. In the case of Adversarial Agents and Adversarial Scenario, this usually manifests itself as a model outputting an adversarial strategy that explores the same AV stack defect or loophole over and over again. This is not only highly inefficient but can also severely limit the amount of issues that can be discovered (i.e. the coverage). Certain strategies can help to reduce this issue (see points C., F. and G. amongst others) to a certain extent. Some strategies reduce Mode Collapse but induce Catastrophic Forgetting (i.e. previous, useful adversarial strategies are “forgotten” in favour of novel adversarial strategies.)

One way of effectively mitigating this is by discretizing and classifying Deep Reinforcement Learning models based on their behaviour and a metric for assessing Mode Collapse. The same Matching and Filtering strategies from above can be used to effectively measure the amount of Mode Collapse of a model during training, both with respect to its previous outputs (i.e. a low-variance detector) and with respect to outputs of other (e.g. stored in a database) models (i.e. a low global diversity detector). Additionally, stopping training when mode collapse happens and classifying and storing these models (storing their parametrisations) allows for a more formal demonstration of coverage over specific CLASSES of Issues.

Similarly, Mode Collapse metrics can be recorded for the duration of training for a specific agent/model. Training can be stopped when mode collapse happens, but a previous state (parametrisation) of the model may be saved—one that corresponds to a state when the model exhibited a higher variance or degree of diversity, i.e. a state where the model scored ‘better’ with respect to one or many Mode Collapse metrics.

An example of such a method is shown in FIG. 8:
a. During training, clone agents when they collapse into a single exploitation mode (according to one or many Mode Collapse metrics) and save agent parametrisations (current or past, depending on desired behaviour and Mode Collapse metric scores) to a Database. Re-start exploration using a new exploration seed. Alternatively re-start training with a re-initialized agent. Repeat iteratively to find a wide variety of adversarial scenarios and train multiple adversarial agents for later testing.
b. During testing, the saved Database of adversarial agents can be used to obtain a diverse set of adversarial scenarios for a given starting seed (positions of agents, road geometry etc.). This means we can test the AV stack against a more diverse set of exploitation modes, increasing our testing coverage. Potential for more formal categorisation of Adversarious Scenarios and Adversarial Agent Behaviour.

Claim—combination of heuristics and learning. Training agent to discover adversarial behaviours. Monitor novelty and distance in latent space or descriptive space of generated trajectories. When determine novelty or variance starts to diminish, save current or past parameterization into a DB along with meta information for classification of types of trajectories being output, then build DB of parameterizations. Effect—terminate training or inference for a policy and switch to a different policy and e.g. new seed, etc to reinitialization of agent. Monitor all over again. Diminishing returns—bail out. Also—formally identifiable classes/clusters of these policies—can run integration/regression tests. E.g. for mining, just a subset of AV stack. Classify on series of descriptors. Mining—smooth trajectories c.f. apply broadly to other environments. Descriptors are being used as interchange format between real, simulated data, inputs, outputs—all inputs and outputs are descriptors, parameterizations are a side product but we care about parameterizations (these are the models)

### I. Anomaly Style Transfer

In one example, the method comprises transforming data comprising physical data and/or simulation data of scenarios with reference to reference data.

Given one or many sets of (automatically-) labelled non-anomalous trajectory data AND one or many sets or (automatically-) labelled, learned or generated anomalous trajectory data, a model can be trained to convert the non-anomalous trajectory data into anomalous trajectory data. Advantageously, this training is unpaired, weakly supervised—without need to label associations between trajectories

One example of such a method may use a Cycle-Consistency Generative Adversarial model, as shown in FIG. 9, to transform the non-anomalous data such that its distribution becomes aligned with the distribution of the anomalous data via the use of Adversarial and Prediction losses. In other words, the method transforms a distribution of non-adversarial trajectories to match a distribution of adversarial trajectories.

It should be understood that anomalous simply means that there is a difference between the distribution of the two types of sets—Any set or sets A can be converted such that their distribution is better aligned to set or sets B.

### J. Defect Report Generation

In one example, the method comprises outputting a defect report and optionally, performing an action in reply to the output defect report.

While the goal of the overall system is Issue Discovery, an important part is represented by derived actionable items from the results of the system and especially from incurred failures. Examples of reports include “field” bugs or bug/defect reports, along with parameterizations for regression and progression testing (e.g. deterministic, fixed simulation scenarios).

Examples of a failure in simulation that may trigger a report:
Simple examples: collision, harsh braking, getting too close to other actors, lane infraction etc.
“Unusual behaviour” with respect to descriptors
Broken ST constraints
Low performance on arbitrary metrics (e.g. prediction/tracking metrics, specific AV component metrics)

In one example, the defect report comprises one or more defects of the ego-vehicle i.e. of the control software of the corresponding AV.

### K. Reproduction of Target Scenarios

See also point E above.

In one example, simulating the first scenario comprises simulating a target scenario.

In this way, the target scenario is used as a seed, for example to simulate a new environment e.g. shuttle in an airport or a particular city/junction/time/traffic/objects/actors.

### L. Proxy

In one example, the method comprises approximating the ego-vehicle or a component thereof as a proxy and wherein simulating the first scenario comprises simulating the first scenario with the proxy. In this way, the ego-vehicle or a component thereof is approximated (downsampled), to accelerate exploration of a relatively reduced search space to discover broad categories at a lower compute cost, before exploring the broad categories using the first agent.

In more detail, the method may include a two stage operation: coarse-to-fine, where a learned, possibly differentiable black-box proxy of the AV stack or one or more of its (sub)components is first used to efficiently reduce the search space, followed by adversarial fine tuning with the real AV stack in the Simulator.

Taking actions and observing states in a Simulated environment can still be expensive and/or time-consuming (even if much cheaper than driving in the real world). This can be due to either a) a slow simulator environment, b) an AV stack that operates at a fixed frequency or c) both.

A learned proxy of the AV software stack or of one or more subcomponents of the AV stack can be used to speed up operation. Two modes of operation are proposed:
1. Swapping the entire AV stack or one or more of its subcomponents with a learned proxy inside the Simulated Environment, to address limitations that arise from the original AV stack (first diagram, bottom)
2. If action labels are present or can be obtained, AV Stack subcomponents differentiable learned proxys can be used to train Adversarial Agents with strong, direct supervision (second diagram, bottom). This addresses both types of limitations.

This is the “coarse” portion of the coarse-to-fine approach because the (imperfect) proxys are used to subsample the search space in an approximate way. The proxys are mere approximators of the distribution of behaviours of the real AV stack (or subcomponents).

The “fine” portion is then represented by fine-tuning of the adversarial agents using the original AV Stack, inside the subsampled search space.
Two stage operation (coarse-to-fine):
First subset the problem space by running with an approximation of a real component (e.g. a learned version of the tracker which would not be so severely time-constrained)
Afterwards explore points in the subset using the full simulation environment

The case of using strong, direct supervision allows for targeting of specific categories of actions (again using the handy trajectory and scenario descriptors from before). E.g. We want to train an Adversarial Agent to induce a specific yaw from the planner—to do this we first train a learned proxy of the planner, freeze the parameters of the proxy and subsequently train an Adversarial Agent to cause the planner proxy to output plans that lead to trajectories that match closely a specific “type” or descriptor.

### M. Auto Regressive

In one example, the method comprises:
simulating a second scenario using the second trajectory;
observing, by the first agent, a second observation of the environment in response to the second trajectory of the first actor; and
optionally, generating, by the first agent, a third trajectory of the first actor based on the observed second observation of the environment.

In one example, the method comprises generating, by the first agent, the first trajectory of the first actor.

That is, the method may comprise repeating the steps of simulating scenarios using generated trajectories, observing the environments and generating trajectories such that the output of the method is the input to the method. In this way, the first agent is trained.

In one example, the method comprises and/or is a method of training the agent. If one example, training the agent comprises establishing, by the agent, a relationship between the first trajectory and the first observation.

### N. Irrecoverable Events

In one example, the method comprises rewarding the first agent if the second observation of the environment in response to the second trajectory of the first actor excludes an irrecoverable event, for example an unavoidable collision of the ego-vehicle with the first actor (i.e. the ego-vehicle cannot prevent the collision due, for example, to physical constraints or the laws of physics).

Existing solutions focus on generating collisions by any means necessary, without considering if collisions are preventable. If the collision is not preventable or avoidable (e.g. an object appears at a distance less than the AV's minimum braking distance in front of it or a pedestrian runs into a stationary AV) the collision is not caused by an AV and therefore does not necessarily represent an issue in the technology used.

In one example, the method comprises cooperating, by the first agent, with a second agent and/or interacting, by the first agent, with an adversarial or non-adversarial agent.

That is, the first agent may interact with second agent and/or behaviours of object i.e. with the environment (non-adversarial objects/agents).

### Simulating Scenarios

The second aspect provides a computer-implemented method of simulating scenarios, the method comprising:
generating a first trajectory of a first actor of a set of actors according to the first aspect;
simulating a first scenario comprising an environment having therein an ego-vehicle, the set of actors, including the first actor, and optionally a set of objects, including a first object, wherein simulating the first scenario comprises using the generated first trajectory of the first actor; and
identifying a defect of the ego-vehicle in the first scenario.

In one example, the method is a method of testing, for example installation, assurance, validation, verification, regression and/or progression testing of the ego-vehicle, for example of the control software thereof.

### Developing Ego-Vehicle

The third aspect provides a computer-implemented method of developing an ego-vehicle, the method comprising:
simulating a scenario according to the second aspect; and
remedying the identified defect of the ego-vehicle.

In one example, remedying the identified defect of the ego-vehicle comprises remedying control software of the ego-vehicle.

### Computer, Computer Program, Non-Transient Computer-Readable Storage Medium

The fourth aspect provides a computer comprising a processor and a memory configured to perform a method according to the first aspect, the second aspect and/or the third aspect.

The fifth aspect provides a computer program comprising instructions which, when executed by a computer comprising a processor and a memory, cause the computer to perform a method according to the first aspect, the second aspect and/or the third aspect.

The sixth aspect provides a non-transient computer-readable storage medium comprising instructions which, when executed by a computer comprising a processor and a memory, cause the computer to perform a method according to the first aspect, the second aspect and/or the third aspect.

### Definitions

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention, such as colourants, and the like.

The term “consisting of” or “consists of” means including the components specified but excluding other components.

Whenever appropriate, depending upon the context, the use of the term “comprises” or “comprising” may also be taken to include the meaning “consists essentially of” or “consisting essentially of”, and also may also be taken to include the meaning “consists of” or “consisting of”.

The optional features set out herein may be used either individually or in combination with each other where appropriate and particularly in the combinations as set out in the accompanying claims. The optional features for each aspect or exemplary embodiment of the invention, as set out herein are also applicable to all other aspects or exemplary embodiments of the invention, where appropriate. In other words, the skilled person reading this specification should consider the optional features for each aspect or exemplary embodiment of the invention as interchangeable and combinable between different aspects and exemplary embodiments.

### BRIEF DESCRIPTION OF THE DRAWINGS

For a better understanding of the invention, and to show how exemplary embodiments of the same may be brought into effect, reference will be made, by way of example only, to the accompanying diagrammatic Figures, in which:

FIG. 1 schematically depicts a scenario of an ego-vehicle;

FIG. 2 schematically depicts labelling of data captured for the scenario from FIG. 1;

FIG. 3 schematically depicts a method of generating a new descriptor from the scenario from FIG. 1 according to one or more embodiments;

FIG. 4 schematically depicts a matcher used in the method schematically depicted in FIG. 3;

FIG. 5 schematically depicts a method of labelling trajectory data as anomalous, according to one or more embodiments;

FIG. 6 schematically depicts respective methods of training and testing a fixed or recurrent trajectory model;

FIG. 7 schematically depicts a method of random network distillation;

FIG. 8 schematically depicts a method or training a policy of an agent from the scenario from FIG. 1 using reinforcement learning according to one or more embodiments;

FIG. 9 schematically depicts respective methods of training and running anomaly conversion using a fixed or recurrent trajectory model according to one or more embodiments;

FIG. 10 schematically depicts a method of training anomaly conversion of first and second fixed or recurrent trajectory models, according to one or more embodiments;

FIG. 11 schematically depicts a method of generating a defect report from an episode of reinforcement learning when training an agent according to one or more embodiments;

FIG. 12 schematically depicts a method of generating a cluster of descriptors for an episode of reinforcement learning when training an agent according to one or more embodiments;

FIG. 13 schematically depicts a method of generating a cluster of descriptors for an episode of reinforcement learning when training an agent according to one or more embodiments;

FIG. 14 schematically depicts a method of generating new descriptors in a descriptor space including the cluster of descriptors from FIGS. 12 and 13 according to one or more embodiments;

FIG. 15 schematically depicts a method of moving away from a plurality of clusters to generate new descriptors according to one or more embodiments;

FIG. 16 schematically depicts a method of scenario reproduction according to one or more embodiments;

FIG. 17 schematically depicts a method of training an agent using reinforcement learning with an environment including a proxy for a software stack of an autonomous vehicle according to one or more embodiments;

FIG. 18 schematically depicts a method of training an agent using reinforcement learning with an environment including a proxy for a software stack component of an autonomous vehicle according to one or more embodiments;

FIGS. 19 to 22 schematically depict the foregoing methods in more detail.

### DETAILED DESCRIPTION OF THE DRAWINGS

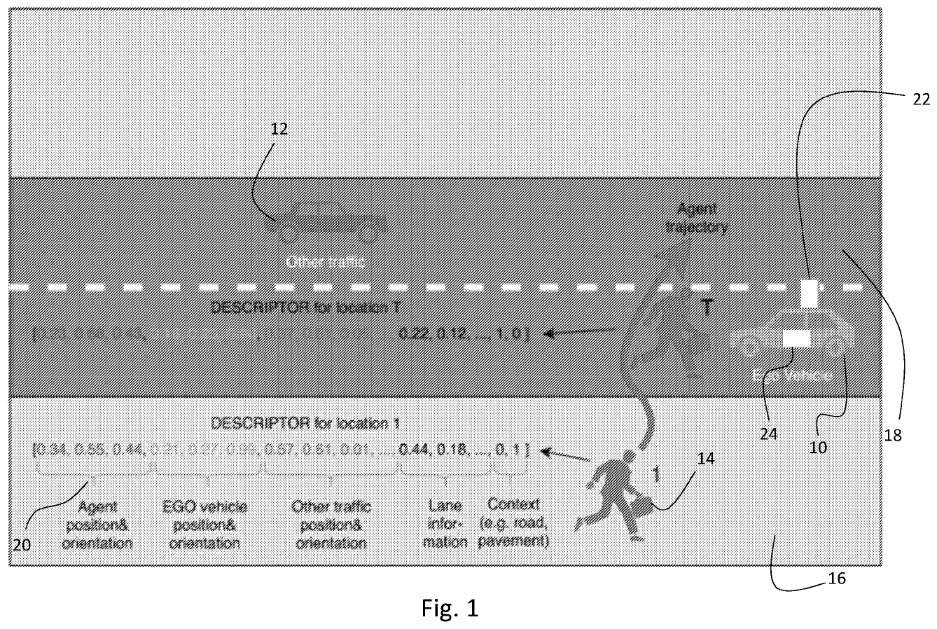

FIGS. 1 to 22 schematically depict a method according to an exemplary embodiment. The method is a computer-implemented method of generating trajectories of actors, the method comprising:
simulating a first scenario comprising an environment having therein an ego-vehicle, a set of actors, including a first actor, and optionally a set of objects, including a first object, wherein simulating the first scenario comprises using a first trajectory of the first actor;
observing, by a first adversarial reinforcement learning agent, a first observation of the environment, for example the ego-vehicle, a second actor of the set thereof and/or the first object of the set thereof, in response to the first trajectory of the first actor; and
generating, by the first agent, a second trajectory of the first actor based on the observed first observation of the environment.

### A. Trajectory and Context Encoding (Descriptors)

FIG. 1 schematically depicts the method according to the exemplary embodiment, in more detail. More specifically, FIG. 1 schematically shows a scenario encountered by an autonomous vehicle 10. The autonomous vehicle 10 may be an ego-vehicle 10. The scenario includes one or more actors, in this particular scenario there are two actors. The two actors include another vehicle 12, and a pedestrian 14. The pedestrian has a trajectory T, e.g. an agent trajectory, moving substantially orthogonally from a sidewalk 16 into a road 18 on which the ego-vehicle 10 is driving. In this way, the agent trajectory intersects the ego-vehicle trajectory. The agent trajectory T is captured as a descriptor 20.

In other words, in this example, the method comprises defining the generated second trajectory as a series of descriptors for respective locations, for example as description-location pairs, in which the description includes one or more components relating to the actor or agent, the ego-vehicle, other actors and the environment. For example, the descriptors may be represented as a series T*(X+N) for T time steps, with X-D positional encoding and N-D encoding for other traffic participants, road configuration and scene context, as described with respect to FIG. 1. Optionally, the descriptors may be represented with normalisation, agent-centric or world-centric expression of coordinates and contexts. In this example, the series of descriptors are heuristics-based and/or learned. In this example, the method comprises deriving the series of descriptors from data comprising physical data and/or simulation data of scenarios.

It should also be noted that the ego-vehicle 10 may include a plurality of sensors 22, and an on-board computer 24. The sensors may include sensors of different modalities including a radar sensors, and image sensor, a LiDAR sensor, and inertial measurement unit (IMU), odometry, etc. The computer 24 may include one or more processors and storage. The ego-vehicle may include one or more actuators, e.g. an engine (not shown), to traverse the ego-vehicle along a trajectory.

### B. Labelling Data

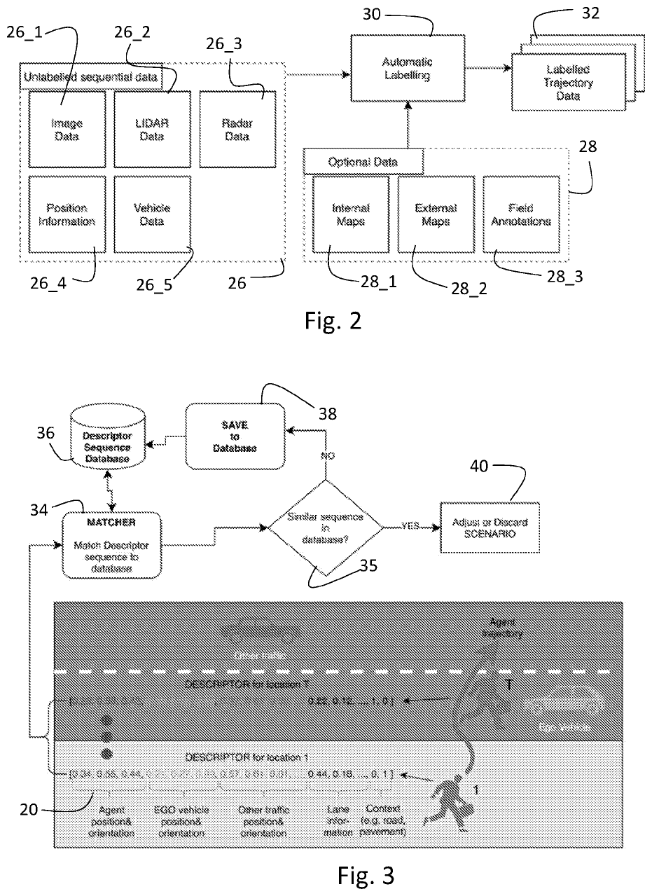

FIG. 2 schematically depicts the method of FIG. 1, in more detail.

In this example, the method comprises labelling the data, for example by applying a perception model thereto, and wherein deriving the series of descriptors from the data comprises deriving the series of descriptors from the labelled data. That is, the data for generating the descriptors is collected and automatically labelled, for example by applying (learned and heuristics-based) perception models to existing sequential data.

In this example, the method comprises identifying respective locations of vehicles from the physical data and/or respective locations of ego-vehicles from the simulation data and wherein deriving the series of descriptors from the data comprises deriving the series of descriptors using the identified respective locations of the vehicles and/or the identified respective locations of the ego-vehicles. That is, localisation techniques can be applied to understand the location of the ego-vehicle in a scene.

In other words, unlabelled sequential data 26 may be captured by the one or more sensors 22 (FIG. 1). The unlabelled sequential data 26 may include image data 26_1, LiDAR data 26_2, Radar Data 26_3, Position Information 26_4, and Vehicle Data 26_5. There may also be provided optional data 28. The optional data 28 may include Internal Maps 28_1, External Maps 282, and Field Annotations 28_3. The Data 26, 28, may be labelled automatically at 30. The result of the automatic labelling may be labelled trajectory data 32.

### C. Avoiding Mode Collapse; Ensuring Novelty

FIG. 3 schematically depicts the method of FIG. 1, in more detail.

In this example, generating, by the first agent, the second trajectory of the first actor comprises predictively or reactively generating, by the first agent, the second trajectory of the first actor.

In this example, the method comprises determining a mutual similarity of a candidate trajectory for the first actor generated by the first agent and a reference trajectory and optionally, generating, by the first agent, the second trajectory of the first actor by modifying the candidate trajectory based on the determined mutual similarity or excluding the candidate trajectory based on the determined mutual similarity.

It should be understood that the candidate trajectory is a candidate for the second trajectory and the reference trajectory may be the first trajectory or a stored trajectory, for example stored in a database and accessed selectively. For example, the candidate trajectory may be compared with trajectories included in a database thereof, which are accessed exhaustively or as a subset based on a classification relevant to the scenario.

In this example, the method comprises rewarding the first agent according to a mutual dissimilarity of the first trajectory and the second trajectory. In this way, the first agent is rewarded for generating novel trajectories.

In other words, a descriptor 20 may be generated for each point of the scenario. The scenario points may be temporal points or location points of the ego-vehicle. The points may each include a position and pose of each actor, or agent, position and pose of the ego-vehicle 10, and context information. The context information may include internal maps and external maps. There may be a plurality of points making up a scenario. Therefore, there may be a plurality of descriptors, each descriptor may be generated for a point. A trajectory T may be a sequence of positions and poses of an agent within the scenario.

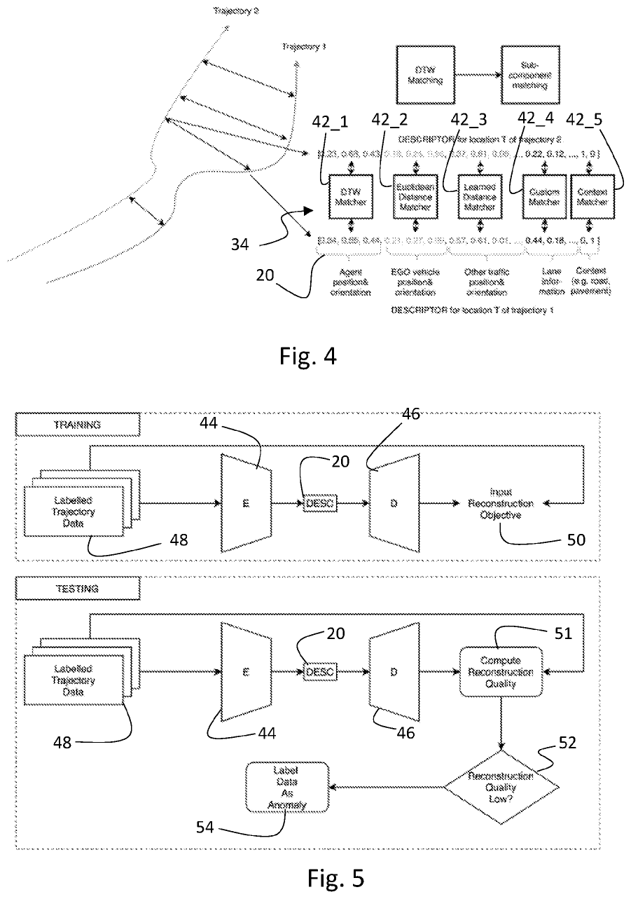

Each descriptor 20 may be input to a matcher 34. The matcher 34 is described in more detail with reference to FIG. 4 below. The matcher 34 compares, at 35, the sequence of descriptors 20 to a descriptor sequence database 36 and determines a degree of similarity, e.g. a distance, between the compared sequences. If the agent trajectory sequence is not similar to any in the database 36, the sequence is stored 38 in the database 36. If the agent trajectory sequence is similar, the agent trajectory sequence is adjusted or discarded 40.

### D. Matching

FIG. 4 schematically depicts the method of FIG. 1, in more detail.

In this example, the method comprises matching the generated second trajectory and a reference trajectory.

One example of matching involves an initial positional matching or filtering using Dynamic Time Warping, followed by one or more stages of matching of other portion of the descriptors based on heuristics (such as Euclidean distance), learned methods (e.g. contrastive or margin) and/or custom combinations of learned and hard-coded rules.

In this example, matching the generated second trajectory and the reference trajectory comprises matching one or more portions of the generated second trajectory and the reference trajectory.

In other words, FIG. 4 schematically depicts the matcher 34 from FIG. 3. The matcher 34 may be configured to compare a similarity between two trajectories, e.g. trajectory 1 (the agent trajectory T), and trajectory 2 (a trajectory stored in database 36). The matcher may include one or more constituent matchers. The constituent matchers may include one or more of a Dynamic Time Warping (DTW) matcher 42_1, a Euclidian distance matcher 42_2, a learned distance matcher 423 (which may be a neural network trained to compute a distance between two sequences of points), a custom matcher 424 (which may be a combination of any other matchers), and a context matcher 42_5.

### E. Reconstruction

FIG. 5 schematically depicts the method of FIG. 1, in more detail.

In this example, the method comprises encoding the generated second trajectory and optionally decoding the encoded second trajectory, computing a reconstruction quality of the decoded second trajectory and labelling the generated second trajectory according to the computed reconstruction quality.

In this example, the method comprises decoding an encoded trajectory, encoding the decoded trajectory and computing a reconstruction quality of the encoded trajectory.

In other words, FIG. 5 schematically depicts training and testing of an autoencoder, more specifically a variational autoencoder (VAE). The VAE may include an encoder 44 and a decoder 46.

During training, the encoder may be configured to generate the descriptor 20 from labelled trajectory data 48. The decoder may be configured to reconstruct trajectory data 50 using the descriptor 20. The encoder and decoder are trained to reduce, or minimise, a loss between the reconstructed trajectory data 50 and the labelled trajectory data 48.

During testing, the reconstructed trajectory may be compared to the original labelled trajectory 48 and a reconstruction quality 51 is computed. If, at 52, the reconstruction quality is low, e.g. below a threshold, the data is labelled as an anomaly at 54. The anomaly 54 may be detected because the reconstructed trajectory is outside the trained distribution. Such an anomaly may thus be a good candidate for using in a simulator to test the AV stack.

### F. Seeding

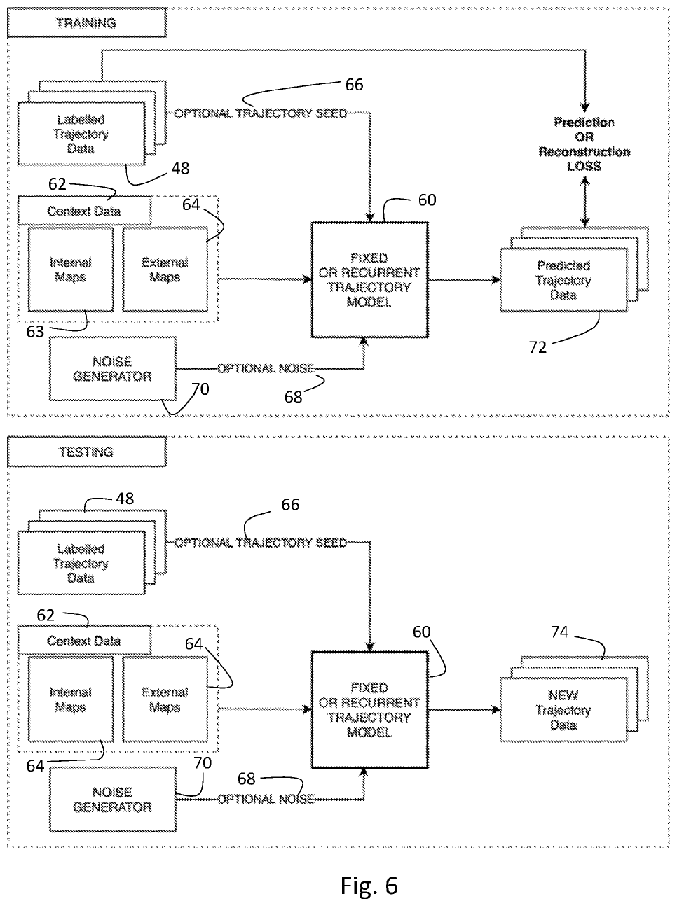

FIG. 6 schematically depicts the method of FIG. 1, in more detail.

In this example, the method comprises seeding an initial state of the first scenario and initializing the first scenario with the seeded initial state.

A proposed method for reducing the number of seed conditions is depicted in FIG. 6. A learned conditional trajectory model is trained to either predict trajectories or generate plausible trajectories (hallucinate) using a combination of real-world data and/or simulation data and/or previously generated adversarial trajectories.

At test time, conditional on a new scene layout (e.g. a previously unencountered road configuration or traffic situation or a portion of a map), the learned model can be used to sample both plausible starting conditions, and plausible future trajectory points given a set of previous trajectory points.

This allows for large-scale informed sampling of scene configurations, scenario seeds and starting points. Additionally, this enables informed Exploration during Reinforcement Learning to balance out Exploitation both to improve coverage and to minimize the chances of Catastrophic forgetting and mode collapse.

In this example, seeding the initial state of the first scenario comprises selecting the initial state from a plurality of initial states. That is, the initial state is purposefully, rather than randomly or systematically, selected, for example so as to optimise exploration.

In other words, the method schematically depicted in FIG. 6 is proposed to reduce the number of seed conditions needed to generate a possibly anomalous trajectory.

A fixed or recurrent trajectory model 60 may be trained in a training stage by inputting context data 62 which may include internal maps 63 and external maps 64. Optionally, a trajectory seed 66 may be input using labelled trajectory data 48, and noise 68 may be input using a noise generator 70. A predicted trajectory 72 may be generated and a prediction or reconstruction loss may be generated. The trajectory model 60 may comprise a neural network. A parameterisation of the trajectory model 60 may be optimised by minimising the prediction or reconstruction loss.

During testing, the trajectory model 60 may generate new trajectory data 74 using the context data 62, the noise 68 and the trajectory seed 66 as inputs.

### G. Rewards

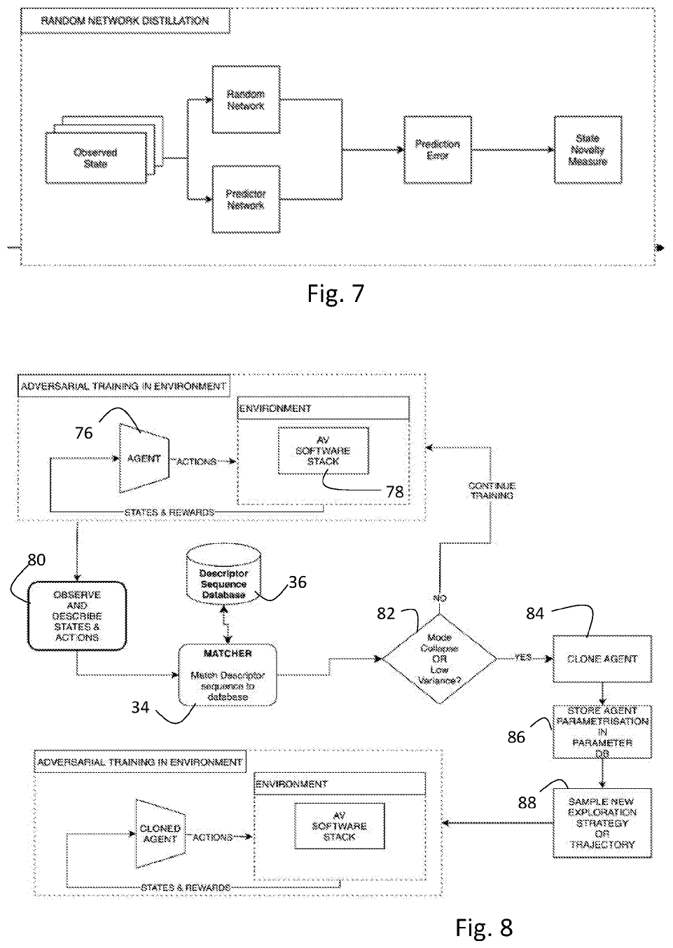

FIG. 7 schematically depicts the method of FIG. 1, in more detail.

In this example, the method comprises rewarding the first agent according to a novelty, for example a short-term novelty and/or a long-term novelty, of the generated second trajectory. In this way, exploration is rewarded.

In more details, the first agent may be rewarded for the novelty of states visited—one example is a voxelized grid to encode extra novelty rewards:
Intrinsic rewards incentivise the RL agent to seek new states and therefore lead to more diverse trajectories taken during training
Rewards can be short-term (e.g. episodic) or long-term (across the training run of the agent), or a combination of both where short-term and long-term novelty is balanced against each other with a scaling coefficient
An example measure of long-term novelty can be obtained by Random Network Distillation (RND). RND uses two networks; a randomly initialised un-trained convolutional neural network (random network) and a predictor convolutional neural network (predictor network) trained during RL training. The predictor network aims to predict the output of the random network for states seen by the RL network. Novel states result in high error in the predictor network's predictions. (This is somewhat similar to using encoders and reconstruction losses, but the RND is trained only on the RL model's observations—rather than a static dataset
so the predictor network's inference errors are specific to a given RL training run. It does however add computation overhead to RL training as it adds an extra network to train).

In this example, the method comprises measuring the novelty, for example using a random network distillation, RND.

### H. Mode Collapse

FIG. 8 schematically depicts the method of FIG. 1, in more detail.

In this example, the method comprises assessing mode collapse of the first agent and adapting the first agent based on a result of the assessment.

An example of such a method is shown in FIG. 8:
a. During training, clone agents when they collapse into a single exploitation mode (according to one or many Mode Collapse metrics) and save agent parametrisations (current or past, depending on desired behaviour and Mode Collapse metric scores) to a Database. Re-start exploration using a new exploration seed. Alternatively re-start training with a re-initialized agent. Repeat iteratively to find a wide variety of adversarial scenarios and train multiple adversarial agents for later testing.
b. During testing, the saved Database of adversarial agents can be used to obtain a diverse set of adversarial scenarios for a given starting seed (positions of agents, road geometry etc.). This means we can test the AV stack against a more diverse set of exploitation modes, increasing our testing coverage. Potential for more formal categorisation of Adversarious Scenarios and Adversarial Agent Behaviour.

In other words, FIG. 8 schematically depicts an adversarial agent 76 which is able to convert a state into an action. Each actor within a scenario may be associated with a unique agent. For example, each agent may govern movement of an actor in response to a given state. An action may be a future position to where an actor has moved, or a speed, or a pose, of the actor etc. The agent 76 may comprise a machine learning algorithm, which may be a neural network.

The AV software stack 78 may include modules including perception and control. The AV software stack may be provided on the computer 24 (FIG. 1) at run-time. The AV software stack 78 may be configured to observe and perceive the environment including the actor governed by the agent 76 and control the ego-vehicle 10 in response to the agent trajectory. In other words, the agent 76 generates an actor trajectory in response to changes of state involving the AV (ego-vehicle).

The agent 76 may be trained using reinforcement learning, or deep reinforcement learning with an environment including the AV software stack 78. Contextual data may also be provided in the environment. For example, there may be no target states that the agent is being trained to match in response to prior input states. Instead, a reward may be used when an episode (e.g. a sequence of states and actions) achieves a goal. For instance, a goal may include an adversarial goal such as an actor colliding with the ego-vehicle. This may happen when an episode includes the actor, e.g. a pedestrian, jumping suddenly from a sidewalk into a road and into the trajectory of the ego-vehicle. In this way, an adversarial event may occur. If there is a defect in the AV stack that means the ego-vehicle does not change course to avoid the actor, this may be captured as an adversarial event.

Other adversarial events may occur too, including those selected from a list including: a collision between the agent (or actor) and the autonomous vehicle, a distance between the agent and the autonomous vehicle being less than a minimum distance threshold, a deceleration of the autonomous vehicle being greater than a deceleration threshold, an acceleration of the autonomous vehicle being greater than an acceleration threshold, and a jerk of the autonomous vehicle being greater than a jerk threshold.

Each episode may terminate in an adversarial event or failure of the AV software stack.

Observations are taken and descriptors of states and actions of the actor may be generated at 80. The descriptors may be generated by an encoder. A matcher, which may include the matcher from FIG. 3, may compare the descriptor to descriptor from a descriptor sequence database 36. The descriptor sequence database 36 may include a plurality of descriptors, wherein each descriptor of the plurality of descriptors includes descriptors of previous episodes. New episodes can be compared by re-initialising the agent and re-performing the reinforcement learning loop to generate a new episode and thus a plurality of new descriptors.

At 82, it is determined if there has been mode collapse. Mode collapse may be determined where there is low variance between the compared episodes. Low variance may be classified as variance below a variance threshold, or convergence variance.

If there has not been mode collapse, e.g. if the agent has generated a new adversarial episode, training is continued. If there has been mode collapse, e.g. the adversarial episode matches a previous adversarial episode, the agent is cloned at 84. At 86, the parameterisation (e.g. the combination of weights within the network) of the agent which caused the adversarial event may be stored in a parameter database. At 88, a new exploration strategy or trajectory may be sampled for the cloned agent. The new exploration strategy may be seeded from an initial state derived from a descriptor from the descriptor sequence database 36.

It is important to note that mode collapse is usually seen as a negative thing. However, mode collapse is used in this scenario to identify anomalous adversarial events so they can used for improving the AV stack using a simulator. In this way, the cloned adversarial agent may be used in the simulator to improve the AV software stack.

### I. Anomaly Style Transfer

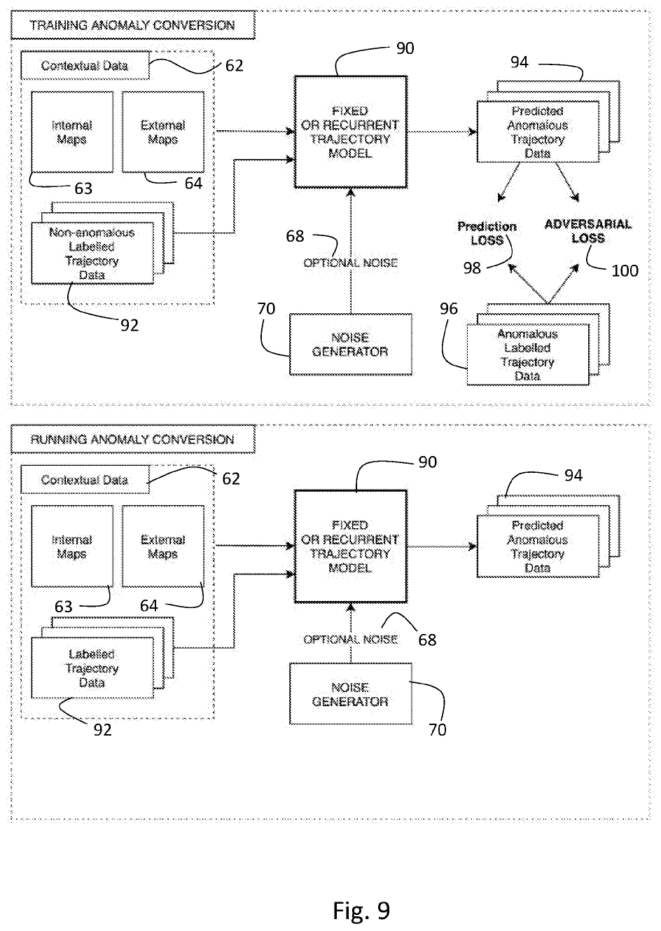

FIG. 9 schematically depicts the method of FIG. 1, in more detail.

In this example, the method comprises transforming data comprising physical data and/or simulation data of scenarios with reference to reference data.

One example of such a method may use a Cycle-Consistency Generative Adversarial model, as shown in FIG. 9, to transform the non-anomalous data such that its distribution becomes aligned with the distribution of the anomalous data via the use of Adversarial and Prediction losses. In other words, the method transforms a distribution of non-adversarial trajectories to match a distribution of adversarial trajectories.

It should be understood that anomalous simply means that there is a difference between the distribution of the two types of sets—Any set or sets A can be converted such that their distribution is better aligned to set or sets B.

The anomalous trajectories may then be explored in the simulator to determine if they are associated with adversarial events e.g. a collision between an agent and the AV, or ego-vehicle.

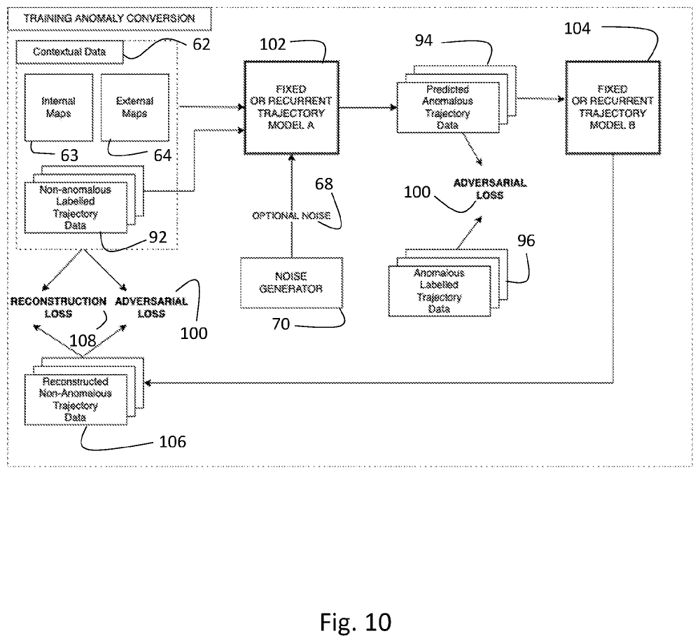

With reference to FIG. 10, there is provided a method of training anomaly conversion using a cycle-consistency GAN, or cycle-consistency generative adversarial model. The model may use similar features to the method and model from FIG. 9 and so duplicate description will be omitted for brevity.

The model may include a first model 102 (or model A), also called a fixed or recurrent trajectory model A, and a second model 104 (or model B), also called a fixed or recurrent trajectory model B. The first model 102 may be configured to generate predicted anomalous trajectory data 94 which is compared to anomalous labelled trajectory data 96 to generate an adversarial loss 100. The predicted anomalous trajectory data 94 may be input to the second model 104 which is configured to generate reconstructed non-anomalous trajectory data 106. A reconstruction loss 108 and an adversarial loss 100 may be obtained by comparing the reconstructed non-anomalous trajectory data to the non-anomalous labelled trajectory data 92. A parameterisation of the second model may be modified to reduce the reconstruction loss 108 and the adversarial loss 100.

In this way, new anomalies, or potentially adversarial events can be synthesized, e.g. using a cycleGAN. Once the new anomalies have been synthesized they can be run through the simulator to test if they are adversarial scenarios, e.g. result in a failure of the AV stack 10.

### J. Defect Report Generation

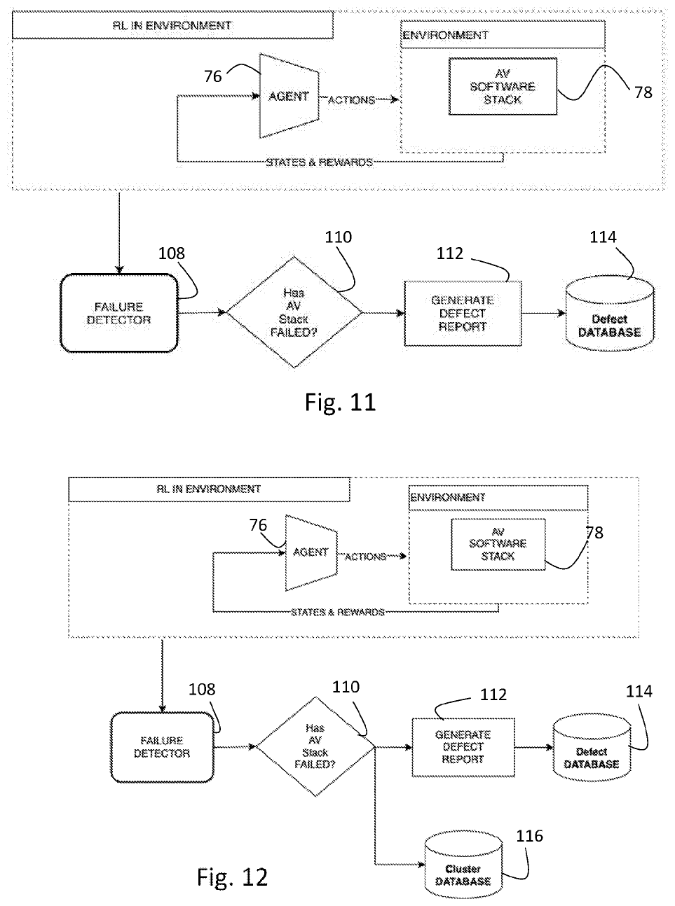

FIG. 11 schematically depicts the method of FIG. 1, in more detail.

In this example, the method comprises outputting a defect report and optionally, performing an action in reply to the output defect report.

In this example, the defect report comprises one or more defects of the ego-vehicle i.e. of the control software of the corresponding AV.

In other words, FIG. 11 schematically depicts in the reinforcement learning environment, failures may be detected (e.g. by a failure detector) 108. The reinforcement learning environment may be in the simulator. Examples of failures include collisions, harsh braking, getting too close to other actors, lane infraction, etc. In other words, failures may be adversarial events as described herein.

At 110, it is questioned if the AV software stack has failed, i.e. has there been a failure. A defect report may be generated at 112. The defect report 112 may be stored in a defect dataset 114.

With reference to FIG. 12, a similar method is provided as depicted in FIG. 11. Similar features will not be described in FIG. 12 and only differences compared to FIG. 11 will. One such difference is the inclusion of a cluster database 116. The cluster database 116 may include clusters of adversarial events.

A plurality, or a set, or points of an episode of reinforcement learning may be clustered together. The plurality of points in the cluster may be added to the cluster database 116.

### Generating New Potentially Adversarial Descriptors

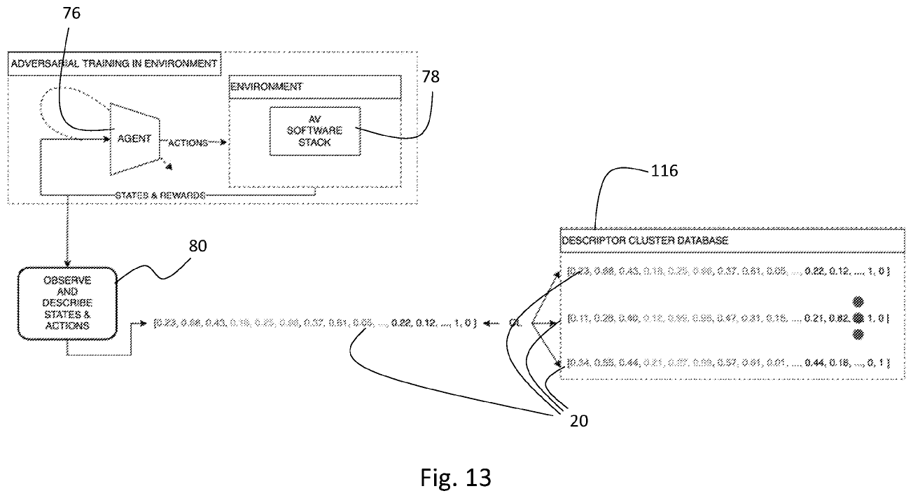

FIG. 13 schematically depicts a method of generating and storing descriptors of adversarial events observed during reinforcement learning of the agent 76. Observations and descriptions are taken at 80 of the states and actions in the episode that resulted in the infraction (also called the adversarial event). The descriptors 20 encoded from the actions and states are stored in the cluster database 116. As described above, the actions and states are clustered according to which episode they relate to.

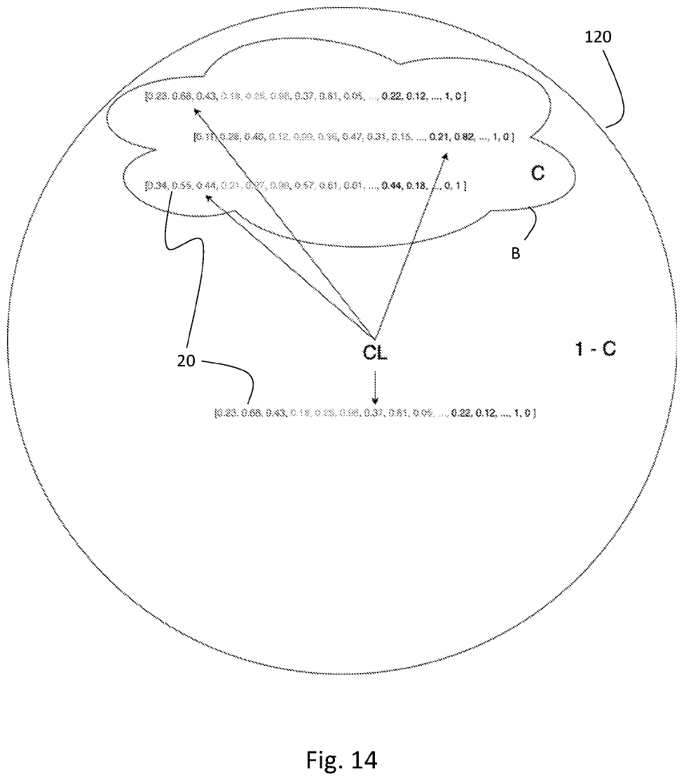

FIG. 14 schematically depicts the cluster database 116 represented as a descriptor space envelope 120. Within the descriptor space envelope 120, there is provided a cluster C of descriptors 20. The cluster includes descriptors which are determined to match one another to within a matching threshold. The clusters may also be determined using a clustering algorithm which may be an unsupervised clustering algorithm.

It is an aim of the subject-matter of the present disclosure to explore the descriptor space envelope to obtain more descriptors of potentially adversarial scenarios that may be tested in a simulator to learn new failures of the AV software stack. It may take an extremely large number of run-time hours to explore the descriptor space envelope on an AV and the processing burden would be excessive and expensive.

Instead, according to one or more embodiments, the descriptor space envelope 120 may be explored by moving away from the currently known cluster C. There are different ways this can be achieved.

One such way involves determining a new descriptor. A direction is determined from a barycentre of the cluster and the new descriptors are generated for incremental positions away from the barycenter in the direction. This may be understood in relation to formula A below.

new descriptor=(C1+C2+ . . . +CN)/N+unit_direction_away_from_super_barycenter×M Formula A:

In Formula A, C1 is a first descriptor, C2 is a second descriptor, CN is an N-th descriptor, and N is a total number of descriptors. This part of formula A effectively calculates a barycenter. In addition, unit_direction_away_from_super_barycenter is a direction, e.g. upwards, downwards, etc. Furthermore, M is a distance away from the barycenter.

Another way to explore the descriptor space envelope 120 is using Formula B.

new descriptor=SDF+unit_direction_away_from_super_barycenter×M. Formula B:

In Formula B, SDF is signed distance function. The other parameters are the same as in Formula A.

Another way to explore the descriptor space envelope 120 is using Formula C.

new descriptor x=\hat{n}_from_p×D. Formula C:

Formula C explores new descriptors by incrementally moving a unit distance from any normal pointing away from a boundary (found using SDF). A boundary B is found using signed distance function (SDF). A normal direction n away from a point p on the boundary B is then explored at a predetermined distance, D. The resulting point location x is then stored as a new descriptor of a potentially adverse scenario for testing on the Simulator.

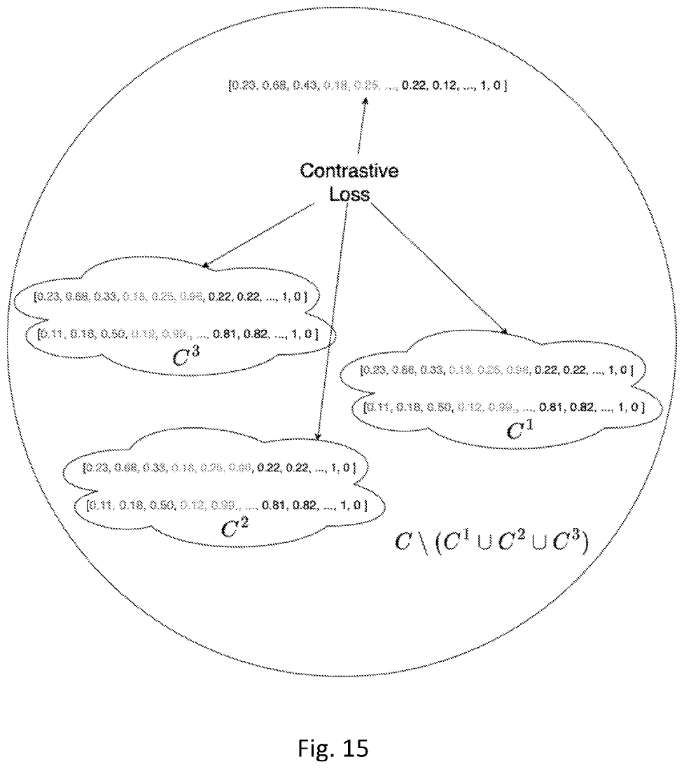

FIG. 15 shows an extension to the idea of exploring the descriptor space envelope from a single cluster as shown in FIG. 14. In FIG. 15, there are three clusters. the moving away from the cluster comprises moving away from the plurality of clusters by: determining a union set between each cluster, C¹∪C²∪C³; determining a difference between the cluster space, C, and the union set using the Formula D; determining a barycentre for the difference; and
generating the new descriptor as a descriptor at the barycentre of the difference

C\(C¹∪C²∪C³). Formula D:

A benefit of this approach is to reduce the chance of searching towards another cluster within the descriptor space envelope.

On a high level, the framework can be described algorithmically as
Initialise set of solution clusters C={ }
For N meta-episodes:
   Initialise policy stochastic policy P with convergence temperature a and an empty replay buffer D (if off-policy)
   Initialise infraction buffer B={ }
   Run episodes until P converges which is detected via a (i.e. policy collapse):
      Until episode terminal conditions (policy collapse) are met:
         Observe states s, take action a, receive reward r, observe new state s′
         Store transitions (s, a, r, s′) in D
      Guide policy away from solutions barycentres in C (if C not empty)
      Optimise policy P based on uniformly sampled transitions from D
      Store each episode that results in an infraction into B
   Cluster new solutions (e.g. descriptors) in B while cross-checking with existing solutions C
   If a new solution is found, add it to C

Where C is a cluster, N is a number of meta-episodes, P is a policy of the agent, a is a convergence temperature or convergence variance, D is a replay buffer, s is a state input to the agent, a is an action output from the agent, r is a reward given to the agent, and s′ is a new state generated by the AV software stack (or sub-component) or proxy (or subcomponent).

### K. Reproduction of Target Scenarios

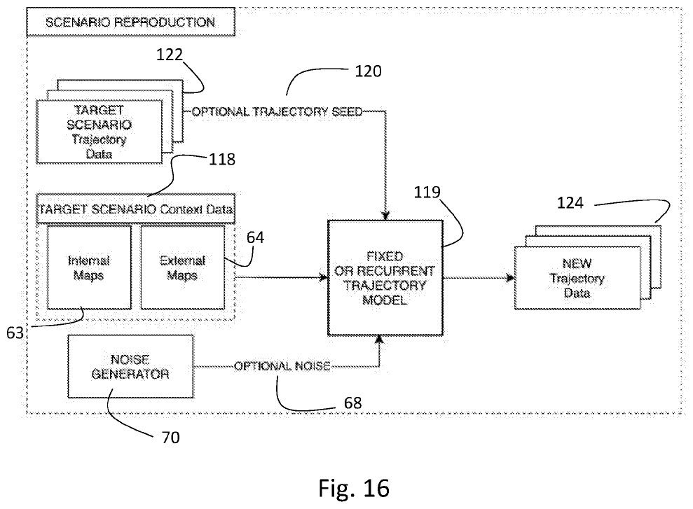

FIG. 16 schematically depicts the method of FIG. 1, in more detail. See also FIG. 6.

In this example, simulating the first scenario comprises simulating a target scenario.

With reference to FIG. 13, the method is a method of generating new trajectory data.

In the method, context data 118 for a target scenario may include internal maps 63 and external maps 64. The context data 118 may be input to a fixed or recurrent trajectory model 119. An optional trajectory seed 120 may be input to the model 119 from a target scenario trajectory data 122. In addition, optional noise 68 may be input to the model 119 from a noise generator 70. The model 119 may be configured to output new trajectory data 124.

### L. Proxy

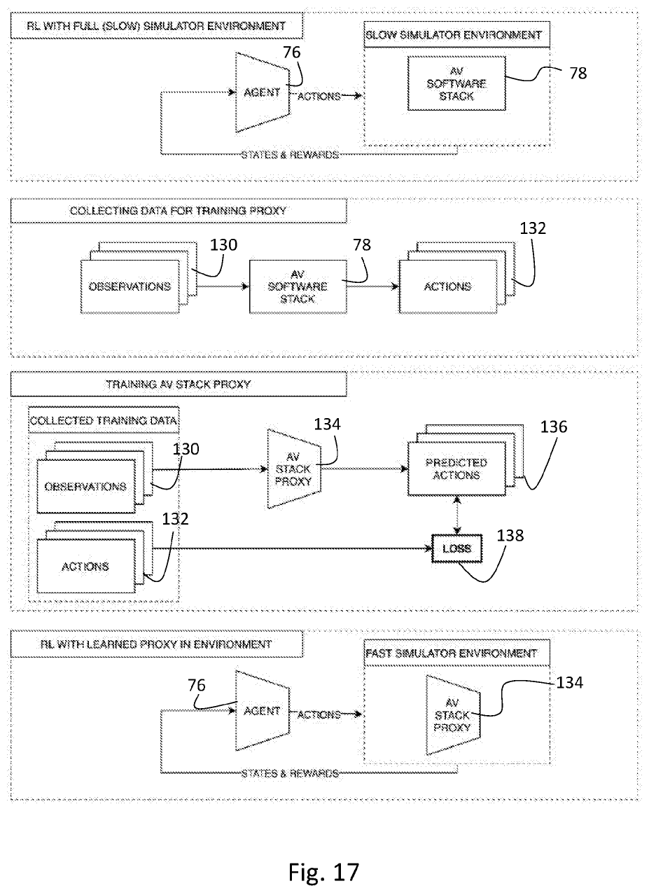

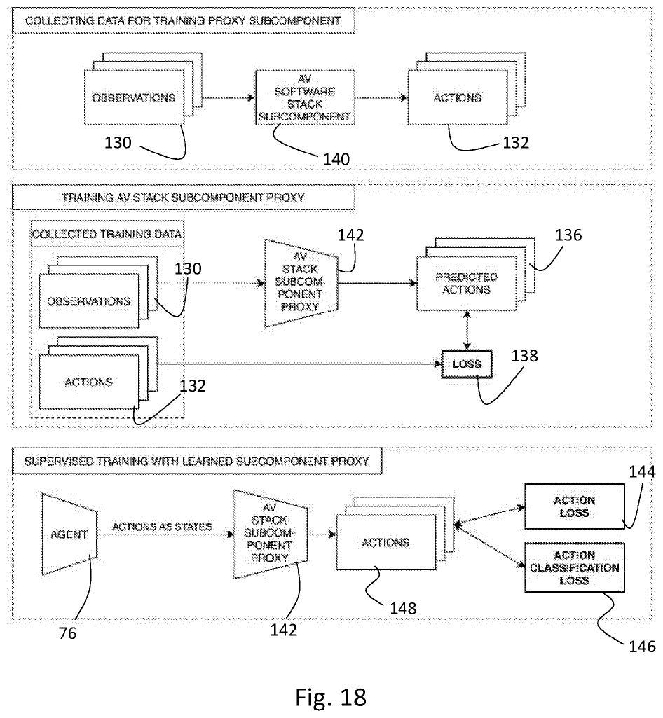

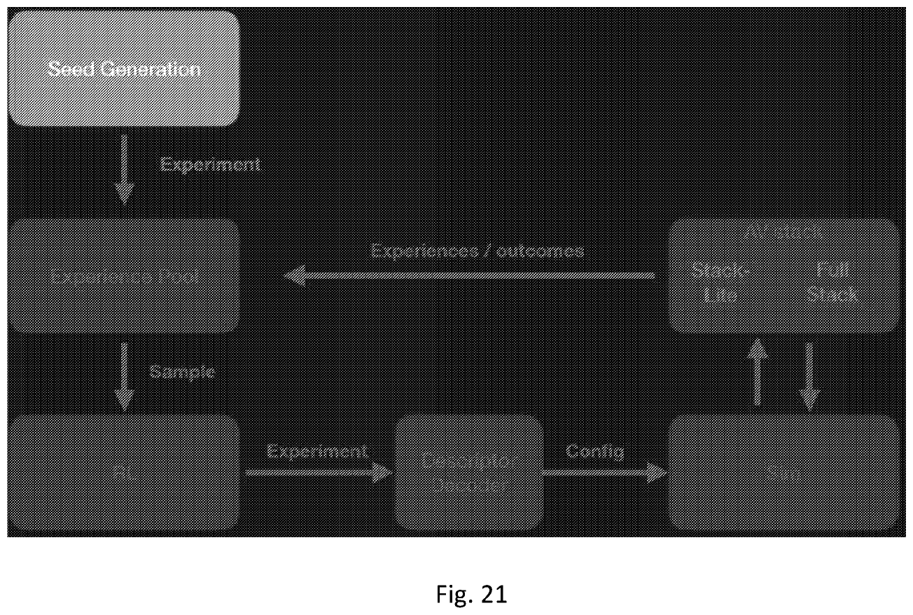

FIGS. 17 and 18 schematically depict the method of FIG. 1, in more detail. See also FIG. 21, in which the AV stack proxy is labelled as Stack-Lite.

In this example, the method comprises approximating the ego-vehicle or a component thereof as a proxy and wherein simulating the first scenario comprises simulating the first scenario with the proxy. In this way, the ego-vehicle or a component thereof is approximated (downsampled), to accelerate exploration of a relatively reduced search space to discover broad categories at a lower compute cost, before exploring the broad categories using the first agent.

In more detail, the method may include a two stage operation: coarse-to-fine, where a learned, possibly differentiable black-box proxy of the AV stack or one or more of its (sub)components is first used to efficiently reduce the search space, followed by adversarial fine tuning with the real AV stack in the Simulator.

Taking actions and observing states in a Simulated environment can still be expensive and/or time-consuming (even if much cheaper than driving in the real world). This can be due to either a) a slow simulator environment, b) an AV stack that operates at a fixed frequency or c) both.

A learned proxy of the AV software stack or of one or more subcomponents of the AV stack can be used to speed up operation. Two modes of operation are proposed:
1. Swapping the entire AV stack or one or more of its subcomponents with a learned proxy inside the Simulated Environment, to address limitations that arise from the original AV stack (first diagram, bottom)
2. If action labels are present or can be obtained, AV Stack subcomponents differentiable learned proxys can be used to train Adversarial Agents with strong, direct supervision (second diagram, bottom). This addresses both types of limitations.

This is the “coarse” portion of the coarse-to-fine approach because the (imperfect) proxys are used to subsample the search space in an approximate way. The proxys are mere approximators of the distribution of behaviours of the real AV stack (or subcomponents).

The “fine” portion is then represented by fine-tuning of the adversarial agents using the original AV Stack, inside the subsampled search space.
Two stage operation (coarse-to-fine):
First subset the problem space by running with an approximation of a real component (e.g. a learned version of the tracker which would not be so severely time-constrained)
Afterwards explore points in the subset using the full simulation environment

The case of using strong, direct supervision allows for targeting of specific categories of actions (again using the handy trajectory and scenario descriptors from before). E.g. We want to train an Adversarial Agent to induce a specific yaw from the planner—to do this we first train a learned proxy of the planner, freeze the parameters of the proxy and subsequently train an Adversarial Agent to cause the planner proxy to output plans that lead to trajectories that match closely a specific “type” or descriptor.

In other words, FIG. 17 shows four different methods. The first method is the method of reinforcement learning of the agent 76 introduced in FIG. 8.

By using the first method, a series of observations 130 observed by the AV software stack 78 and a series of actions 132 performed by the AV stack 130 in response to the observations are generated in the second method.

In the third method, an AV stack proxy 134 is used instead of the AV software stack 78. The AV stack proxy may be a machine learning model, such as a neural network. The neural network may be a convolutional neural network, CNN.

The AV stack proxy 134 may be trained according to the third method. The AV stack proxy 134 may be trained by generating predicted actions 136 based on input observations 130. A loss 138 between the predicted actions 136 and the actions generated in the second method may be obtained. A parameterisation of the AV stack proxy may be optimised to reduce, or minimise, the loss 138.

In the fourth method, reinforcement learning of the agent 76 occurs using states and rewards generated by the AV stack proxy 134 in the simulator.

Since the AV stack proxy is a smaller model than the entire AV software stack, anomalies and adversarial scenarios can be determined faster. It will be appreciated that anomalies found using the AV stack proxy 134 may be considered approximations. To determine if the scenarios are actually adversarial or not, the first method will be used to validate the anomalies as adversarial scenarios where the AV software stack 78 has failed.

The approximations of the adversarial events may form clusters in a way shown in FIG. 15. Again, each of the clusters may have a barycentre. Once the clusters are found using the coarse approximations with the AV stack proxy 134, the method according to FIG. 16 (and FIG. 14) may be used to explore the descriptor space to discover new potentially adversarial scenarios that can be tested using the full AV software stack 78 on the simulator. This approach is much more computationally efficient and also reduces the amount of time needed to explore the descriptor space.

The same approach can be used with a sub-component of the AV software stack 140, e.g. semantic segmentation, or object recognition.

With reference to FIG. 18, there is provided a method of obtaining approximate failures of a subcomponent of the AV software stack 140. FIG. 18 schematically depicts three methods.

In a first method, observations 130 are input to the AV software stack subcomponent 140 which generates actions 132 in response.

In a second method, the observations 130 and actions 132 form collected training data. An AV stack subcomponent proxy 142 is trained using the collected training data. Specifically, the AV stack subcomponent proxy 142 generates predicted actions using the observations 130. A loss is determined between the predicted actions 136 and the actions 132. A parameterisation of the AV stack subcomponent proxy 142 is trained to reduce, or minimise, the loss 138. The AV stack subcomponent proxy 142 may be, or comprise, a machine learning model, such as a neural network. The neural network may be a convolutional neural network CNN.

The third method may be a method of supervised training with the learned subcomponent proxy 142.

The learned subcomponent proxy 142 may generate actions based on actions 148 from the agent 76. An action loss 144 and an action classification loss 146 may be calculated to train the agent 76.

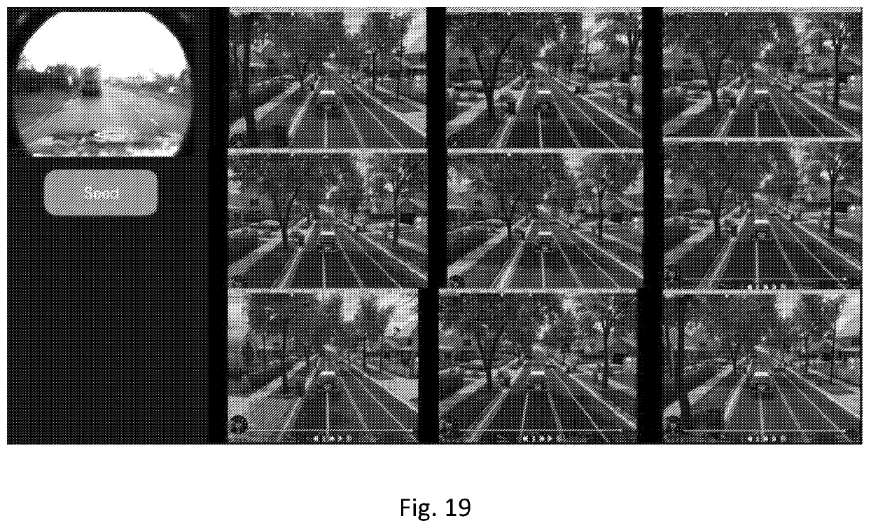

FIG. 19 schematically depicts the method of FIG. 1, in more detail. Particularly, FIG. 19 shows nine scenarios simulated using a seed, to explore response of the ego-vehicle.

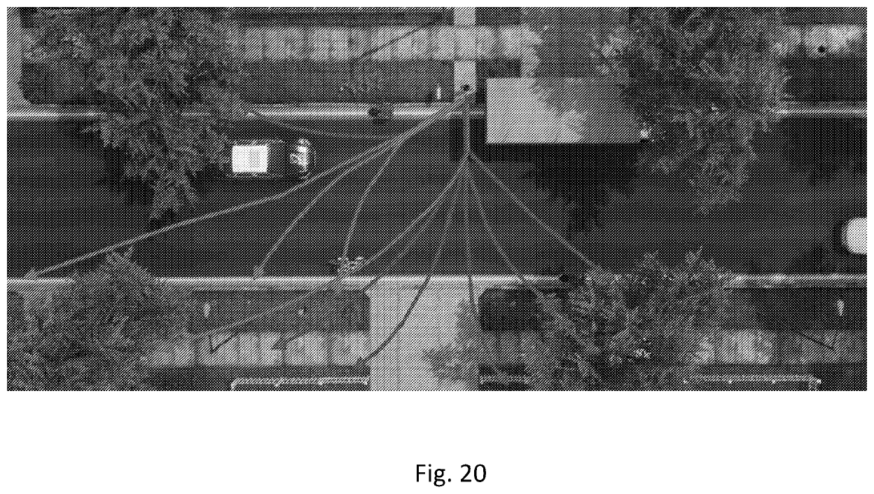

FIG. 20 schematically depicts the method of FIG. 1, in more detail. Particularly, FIG. 21 shows a scenario including a plurality of candidate trajectories of the first actor (a pedestrian).

However, the respective starting points of the plurality of candidate trajectories is the same starting point and hence the first agent is rewarded to change the respective starting points, while excluding unavoidable collisions of the ego-vehicle with the first actor, such as in front of the truck.

FIG. 21 schematically depicts the method of FIG. 1, in more detail. In FIG. 21 the stack lite may correspond to the AV software stack proxy or the AV software stack subcomponent proxy.

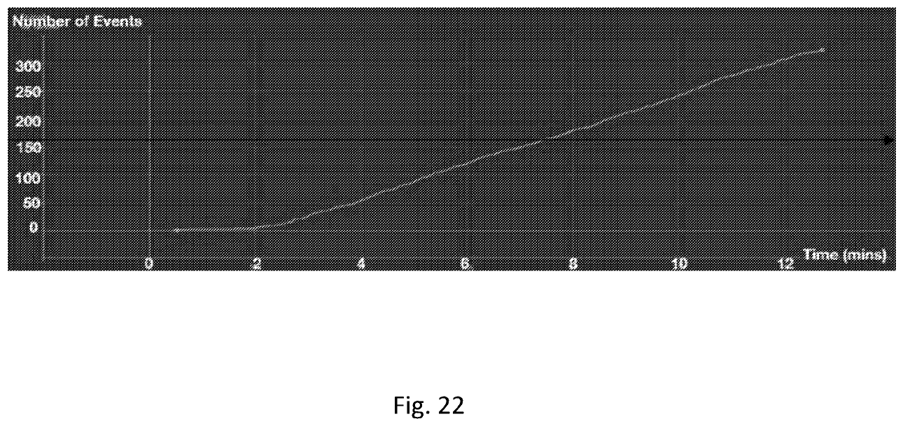

FIG. 22 is a graph of a number of events (trajectories) generated as a function of time according to the method of FIG. 1. Particularly, the method generates in excess of 300 events in about 13 minutes, thereby improving discovery of defects of the ego-vehicle and hence of the control software of the corresponding vehicle.

Although a preferred embodiment has been shown and described, it will be appreciated by those skilled in the art that various changes and modifications might be made without departing from the scope of the invention, as defined in the appended claims and as described above.

At least some of the example embodiments described herein may be constructed, partially or wholly, using dedicated special-purpose hardware. Terms such as ‘component’, ‘module’ or ‘unit’ used herein may include, but are not limited to, a hardware device, such as circuitry in the form of discrete or integrated components, a Field Programmable Gate Array (FPGA) or Application Specific Integrated Circuit (ASIC), which performs certain tasks or provides the associated functionality. In some embodiments, the described elements may be configured to reside on a tangible, persistent, addressable storage medium and may be configured to execute on one or more processors. These functional elements may in some embodiments include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. Although the example embodiments have been described with reference to the components, modules and units discussed herein, such functional elements may be combined into fewer elements or separated into additional elements. Various combinations of optional features have been described herein, and it will be appreciated that described features may be combined in any suitable combination. In particular, the features of any one example embodiment may be combined with features of any other embodiment, as appropriate, except where such combinations are mutually exclusive. Throughout this specification, the term “comprising” or “comprises” means including the component(s) specified but not to the exclusion of the presence of others.

Attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

The subject-matter of the present disclosure may be expressed by the following clauses.
1. A computer-implemented method of generating trajectories of actors, the method comprising: simulating a first scenario comprising an environment having therein an ego-vehicle, a set of actors, including a first actor, and optionally a set of objects, including a first object, wherein simulating the first scenario comprises using a first trajectory of the first actor;
observing, by a first adversarial reinforcement learning agent, a first observation of the environment, for example the ego-vehicle, a second actor of the set thereof and/or the first object of the set thereof, in response to the first trajectory of the first actor; and
generating, by the first agent, a second trajectory of the first actor based on the observed first observation of the environment.
2. The method according to any previous clause, comprising defining the generated second trajectory as a series of descriptors for respective locations, for example as description-location pairs.
3. The method according to clause 2, wherein the series of descriptors are heuristics-based and/or learned.
4. The method according to any of clauses 2 to 3, comprising deriving the series of descriptors from data comprising physical data and/or simulation data of scenarios.
5. The method according to clause 4, comprising labelling the data, for example by applying a perception model thereto, and wherein deriving the series of descriptors from the data comprises deriving the series of descriptors from the labelled data.
6. The method according to any of clauses 4 to 5, comprising identifying respective locations of vehicles from the physical data and/or respective locations of ego-vehicles from the simulation data and wherein deriving the series of descriptors from the data comprises deriving the series of descriptors using the identified respective locations of the vehicles and/or the identified respective locations of the ego-vehicles.
7. The method according to any previous clause, wherein generating, by the first agent, the second trajectory of the first actor comprises predictively or reactively generating, by the first agent, the second trajectory of the first actor.
8. The method according to clause 7, comprising determining a mutual similarity of a candidate trajectory for the first actor generated by the first agent and a reference trajectory and optionally, generating, by the first agent, the second trajectory of the first actor by modifying the candidate trajectory based on the determined mutual similarity or excluding the candidate trajectory based on the determined mutual similarity.
9. The method according to any of clauses 7 to 8, comprising rewarding the first agent according to a mutual dissimilarity of the first trajectory and the second trajectory.
10. The method according to any previous clause, comprising matching the generated second trajectory and a reference trajectory.
11. The method according to clause 10, wherein matching the generated second trajectory and the reference trajectory comprises matching one or more portions of the generated second trajectory and the reference trajectory.
12. The method according to any previous clause, comprising encoding the generated second trajectory and optionally decoding the encoded second trajectory, computing a reconstruction quality of the decoded second trajectory and labelling the generated second trajectory according to the computed reconstruction quality.
13. The method according to any previous clause, comprising decoding an encoded trajectory, encoding the decoded trajectory and computing a reconstruction quality of the encoded trajectory.
14. The method according to any previous clause, comprising seeding an initial state of the first scenario and initializing the first scenario with the seeded initial state.
15. The method according to clause 14, wherein seeding the initial state of the first scenario comprises selecting the initial state from a plurality of initial states.
16. The method according to any previous clause, comprising rewarding the first agent according to a novelty, for example a short-term novelty and/or a long-term novelty, of the generated second trajectory.
17. The method according to clause 16, comprising measuring the novelty, for example using a random network distillation, RND.
18. The method according to any previous clause, comprising assessing mode collapse of the first agent and adapting the first agent based on a result of the assessment.
19. The method according to any previous clause, comprising transforming data comprising physical data and/or simulation data of scenarios with reference to reference data.
20. The method according to any previous clause, comprising outputting a defect report and optionally, performing an action in reply to the output defect report.
21. The method according to any previous clause, comprising approximating the ego-vehicle or a component thereof as a proxy and wherein simulating the first scenario comprises simulating the first scenario with the proxy.
22. The method according to any previous clause, comprising:
generating, by the first agent, the first trajectory of the first actor; and/or
simulating a second scenario using the second trajectory;
observing, by the first agent, a second observation of the environment in response to the second trajectory of the first actor; and
optionally, generating, by the first agent, a third trajectory of the first actor based on the observed second observation of the environment.
23. The method according to clause 22, comprising rewarding the first agent if the second observation of the environment in response to the second trajectory of the first actor excludes an irrecoverable event, for example an unavoidable collision of the ego-vehicle with the first actor.
24. The method according to any previous clause, comprising cooperating, by the first agent, with a second agent and/or interacting, by the first agent, with an adversarial or non-adversarial agent.
25. The method according to any previous clause, wherein generating, by the first agent, the second trajectory of the first actor based on the observed first observation of the environment comprises exploring, by the first agent, outside a normal space.

1. A computer-implemented method of generating a new adversarial scenario involving an autonomous vehicle and an agent, the method comprising:
performing reinforcement learning to train the agent using a proxy of an autonomous vehicle software stack in a reinforcement learning environment to generate one or more episodes, the one or more episodes each representing an adversarial scenario terminating in failure of the proxy of the autonomous vehicle software stack;
generating a plurality of descriptors based on each of the one or more episodes; and
storing the plurality of descriptors in a database.

2. The computer-implemented method of claim 1, comprising clustering the plurality of descriptors, to obtain a cluster of descriptors and wherein storing the plurality of descriptors comprises storing the cluster of descriptors in the database.

3. The computer-implemented method of claim 2, further comprising generating a new descriptor by moving away from the cluster of descriptors in a descriptor space.

4. The computer-implemented method of claim 3, wherein moving away from the cluster of descriptors in the descriptor space comprises:
identifying a barycentre for the cluster of descriptors;
moving away from the barycentre in a unit direction by a unit amount to a new descriptor location; and
generating the new descriptor as a descriptor at the new descriptor location.

5. The computer-implemented method of claim 3, wherein moving away from the cluster of descriptors in the descriptor space comprises:
identifying a set boundary for the cluster of descriptors;
moving away from the boundary in a unit direction by a unit amount to a new descriptor location; and
generating the new descriptor as a descriptor at the new descriptor location.

6. The computer-implemented method of claim 3, wherein moving away from the cluster of descriptors in the descriptor space comprises:
identifying a set boundary for the cluster of descriptors;
moving away from the boundary in a locally normal direction by a unit amount to a new descriptor location; and
generating the new descriptor as a descriptor at the new descriptor location.

7. The computer-implemented method of claim 5, wherein the set boundary is identified using a signed distance function.

8. The computer-implemented method of claim 3, wherein the one or more episodes comprises a plurality of episodes, clustering the plurality of episodes comprises generating a plurality of clusters, and storing the plurality of descriptors comprises storing the plurality of clusters in the database, wherein moving away from the cluster of descriptors comprises moving away from the plurality of clusters by:
determining a union set between each cluster in the plurality of clusters;
determining a difference between the cluster space and the union set;
determining a barycentre for the difference; and
generating the new descriptor as a descriptor at the barycentre of the difference.

9. The computer-implemented method of claim 3, further comprising:
generating a seed state from the new descriptor; and
re-performing: the reinforcement learning using the seed state, the generating the plurality of descriptors, and the storing the plurality of descriptors.

10. The computer-implemented method of claim 1, further comprising:
re-initialising the agent; and
re-performing: the reinforcement learning using the re-initialised agent, the generating the plurality of descriptors, and the storing the plurality of descriptors.

11. The computer-implemented method of claim 1, wherein the reinforcement learning environment further comprises contextual data.

12. The computer-implemented method of claim 11, wherein the contextual data comprises one or more internal maps and/or one or more external maps.

13. The computer-implemented method of claim 11, further comprising:
changing the contextual data in the reinforcement learning environment; and
re-performing: the reinforcement learning using the changed contextual data, the generating the plurality of descriptors, and the storing the plurality of descriptors.

14. The computer-implemented method of claim 1, wherein:
at least one of the one or more episodes comprises a plurality of points; and
each point comprises a state output by the reinforcement learning environment and an action output by the agent.

15. The computer-implemented method of claim 14, wherein generating the plurality of descriptors comprises encoding the plurality of points to a latent space.

16. The computer-implemented method of claim 1, wherein the failure comprises an event selected from a list including at least one of: a collision between the agent and the autonomous vehicle software stack, a distance between the agent and the autonomous vehicle software stack being less than a minimum distance threshold, a deceleration of the autonomous vehicle software stack being greater than a deceleration threshold, an acceleration of the autonomous vehicle software stack being greater than an acceleration threshold, and a jerk of the autonomous vehicle software stack being greater than a jerk threshold.

17. The computer-implemented method of claim 1, wherein the proxy comprises a machine learning mode.

18. A computer implemented method of generating an agent from a scenario involving an autonomous vehicle, the computer-implemented method comprising:
providing an agent trained using reinforcement learning in an environment with a proxy of an autonomous vehicle software stack,
performing reinforcement learning to optimise the agent using a full autonomous vehicle software stack upon which proxy is based.

19. (canceled)

20. A transitory, or non-transitory, computer-readable storage medium having instructions stored thereon that when executed by one or more processors, cause the one or more processors to:
perform reinforcement learning to train an agent using a proxy of an autonomous vehicle software stack in a reinforcement learning environment to generate one or more episodes, the one or more episodes each representing an adversarial scenario terminating in failure of the proxy of the autonomous vehicle software stack;
generating a plurality of descriptors based on each of the one or more episodes; and
storing the plurality of descriptors in a database.

21. The computer-implemented method of claim 6, wherein the set boundary is identified using a signed distance function.

22. The computer-implemented method of claim 17, wherein the machine learning model is a neural network.

23. The computer-implemented method of claim 22, wherein the neural network is a convolutional neural network.
